(19) United States
(12) Patent Application Publication
(10) Pub. No.: US 2024/0363598 A1
(43) Pub. Date: Oct. 31, 2024

(54) LED TRANSFER DEVICE AND TRANSFERRING METHOD USING THE SAME

(71) Applicant: Samsung Display Co., LTD., Yongin-si (KR)

(72) Inventors: Jeong Won HAN, Yongin-si (KR); Won Hee OH, Yongin-si (KR)

(21) Appl. No.: 18/625,111

(22) Filed: Apr. 2, 2024

(30) Foreign Application Priority Data
Apr. 27, 2023 (KR) 10-2023-0055373

(51) Int. Cl. H01L 25/075

(52) U.S. Cl. CPC H01L 25/0753

(57) ABSTRACT

A transfer device of a light-emitting element, the transfer device including: a transferer including a transferring portion, a folding portion at an edge, a stamp layer having a tacky or adhesive surface, and a base layer above one surface of the stamp layer; a protective film above an other surface of the stamp layer, and defining an incision groove with the transferring portion at a center thereof on a plane; an inverter for inverting up, down, left, and right sides of the transferer, and including a support chuck configured to adsorb the protective film overlapping the transferring portion, and a side chuck configured to adsorb the protective film overlapping the folding portion; a transfer head having a head chuck configured to be adsorbed to the base layer, and movable up, down, left, and right; and a folder including a detachable first clamp.

### CROSS-REFERENCE TO RELATED APPLICATION

The present application claims priority to and the benefit of Korean Patent Application No 10-2023-0055373, filed on Apr. 27, 2023, in the Korean Intellectual Property Office, the entire disclosure of which is incorporated by reference herein.

### BACKGROUND

### 1. Field

The present disclosure relates to a transfer device and a transferring method using the same.

### 2. Description of the Related Art

The importance of display devices is increasing along with the development of multimedia. In response, several types of display devices are being used, such as organic light-emitting diode (OLED) display and liquid crystal displays (LCD).

A device for displaying an image of a display device includes a display panel such as a light-emitting display panel or a liquid crystal display panel. Among them, the light-emitting display panel may include a light-emitting diode (LED). The light-emitting diode includes an organic light-emitting diode (OLED) using an organic material as a fluorescent material or an inorganic light-emitting diode using an inorganic material as a fluorescent material.

In the manufacture of display panels utilizing the inorganic light-emitting diode as a light-emitting diodes, manufacturing devices and methods for disposing micro LED on a substrate of the display panel is desired.

### SUMMARY

Aspects of embodiments of the present disclosure provide a transfer device of a light-emitting element that folds up the folding unit after removing the protective film attached to the folding unit.

According to one or more embodiments, it is possible to reduce or prevent the likelihood of the phenomenon that the protective film is unwantedly removed or pushed during folding by folding a transfer member after removing the protective film.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, transfer device of a light-emitting element includes: a transferer comprising a transferring portion, a folding portion at an edge, a stamp layer having a tacky or adhesive surface, and a base layer above one surface of the stamp layer; a protective film above an other surface of the stamp layer, and defining an incision groove with the transferring portion at a center thereof on a plane; an inverter for inverting up, down, left, and right sides of the transferer, and comprising a support chuck configured to adsorb the protective film overlapping the transferring portion, and a side chuck configured to adsorb the protective film overlapping the folding portion; a transfer head having a head chuck configured to be adsorbed to the base layer, and movable up, down, left, and right; and a folder comprising a detachable first clamp.

According to one or more embodiments, the folder further includes: a clamp support defining a first groove in which the transferring portion of the transferer is able to be seated; and a clamp fixture around the first groove, wherein the first clamp is detachably on the clamp fixture, and is configured to fix the folding portion that is folded.

According to one or more embodiments, the first clamp is in divided units that are inclined in a first groove direction, and is in a structure that becomes narrower as it goes downward and that is configured to guide the transferer to the first groove.

According to one or more embodiments, the transfer head includes: a body; the head chuck at a center of the body, and configured to be adsorbed to the transferring portion of the transferer; and a second clamp movable between an edge of the body and the head chuck.

According to one or more embodiments, the second clamp is configured to fix the first clamp for fixing the folding portion that is folded.

According to one or more embodiments, a transfer device of a light-emitting element includes: a transferer comprising a transferring portion, a folding portion at an edge, a stamp layer having a tacky or adhesive surface, and a base layer above one surface of the stamp layer; a protective film above the other surface of the stamp layer, and defining an incision groove an a center thereof on a plane; an inverter above a support chuck capable of adsorbing the protective film overlapping with the transferring portion, and configured to invert up, down, left, and right sides of the transferer; a transfer head having a head chuck adsorbed to the base layer and movable up, down, left, and right; a vertical mover adjacent to the support chuck, capable of vertical movement; and side chuck for adsorbing the protective film overlapping the folding portion.

According to one or more embodiments, the folding portion is foldable around the incision groove by upward driving of the vertical mover.

According to one or more embodiments, the transfer head includes: a body; the head chuck at a center of the body, and configured to be adsorbed to the transferring portion of the transferer; and a clamp movable between the edge of the body and the head chuck, and fixable to the folding portion that is folded.

According to one or more embodiments, the inverter is attached to a front end of a body of an articulated robot having joints.

According to one or more embodiments, a transfer device of a light-emitting element including: a transferer comprising a transferring portion, a folding portion at an edge, a stamp layer having a tacky or adhesive surface, and a base layer above one surface of the stamp layer; a protective film above the other surface of the stamp layer, and defining an incision groove with the transferring portion at a center thereof on a plane; a inverter for inverting up, down, left, and right sides of the transferer; a transfer head having a head chuck adsorbed to the base layer and movable up, down, left, and right; and a loader having chucks configured to be adsorbed to the protective film of the transferer; support chuck below the loader, and configured to adsorb the protective film overlapping with the transferring portion; a vertical mover adjacent to the support chuck and configured to perform vertical movement; and a side chuck configured to adsorb the protective film overlapping the folding portion.

According to one or more embodiments, further including a cutter for forming a cutting groove of the transferer, and comprising a first cutter for cutting the transferer to an arbitrary size from an original sheet of the transferer to which the protective film is attached, a second cutter for forming the incision groove penetrating the protective film, and a chuck configured to adsorb the transferer.

According to one or more embodiments, the folding portion is foldable around the incision groove by upward driving of the vertical mover.

According to one or more embodiments, the transfer head includes: a body; the head chuck at a center of the body and configured to be adsorbed to the transferring portion of the transferer; and a clamp movable between the edge of the body and the head chuck, and fixable to the folding portion that is folded.

According to one or more embodiments, the light-emitting element comprises an n-type semiconductor, an active layer, a p-type semiconductor, a first contact electrode, and a second contact electrode.

According to one or more embodiments, a method of transferring a light-emitting element including: cutting an original sheet of a transferer having a protective film on a support into a size of a transferring portion, and forming an incision groove on the protective film to define a folding portion and the transferring portion; inverting up, down, left, and right sides of transferers using a inverter; peeling off the protective film attached to the folding portion by a side chuck of the inverter; folding the transferer in the folding portion with a first clamp of the folding portion around the incision groove; fixing the folding portion that is folded in a state where a transfer head is configured to adsorb the transferring portion; fixing the first clamp by a second clamp of the transfer head; lifting the transferer that is folded by the first clamp; peeling off the protective film of the transferring portion; picking up the light-emitting element from a donor substrate by adsorption; lifting the light-emitting element to the transferring portion by the transfer head; unclamping the first clamp and the second clamp; attaching the first clamp to the folding portion; aligning the light-emitting element on a circuit board by the transfer head; and detaching the transferer from the transfer head.

According to one or more embodiments, the folding portion includes: a clamp support defining a first groove for seating the transferring portion; a clamp fixture around the first groove; and the first clamp detachably on the clamp fixture, and configured to fix the folding portion that is folded, wherein the transferring portion of the transferer is seated in the first groove, the folding portion of the transferer is folded around the incision groove, the first clamp supports the folding portion, and the second clamp of the transfer head fixes the first clamp.

According to one or more embodiments, the method further includes: bonding the light-emitting element attached to the transferer onto the circuit board; and removing the transferer by peeling it from the light-emitting element bonded to the circuit board by the transfer head.

According to one or more embodiments, the transferer comprises a base layer, and a stamp layer above one surface of the base layer and comprising a material having tacky or adhesive properties, and wherein the protective film is above another side of the stamp layer.

According to one or more embodiments, the base layer, the stamp layer, and the protective film are sequentially on the support.

According to one or more embodiments, a method of transferring a light-emitting element includes: cutting an original sheet of a transferer having a protective film on a support into size of a transferring portion; forming an incision groove on the protective film to define a folding portion and the transferring portion; picking up the transferer using an inverter; inverting the transferer up, down, left, and right; folding up the folding portion by adsorbing the protective film attached to the folding portion by a side chuck of the inverter and raising a vertical mover of the inverter below the folding portion in a state in which a transfer head configured to adsorb the transferring portion; fixing the folding portion that is folded with a clamp of the transfer head; lifting the transferer; peeling off the protective film of the transferer; picking up the light-emitting element from a donor substrate by adhering the light-emitting element to the transferer by the transfer head; detaching the clamp from the folding portion by releasing the clamp and fixing the clamp to the folding portion; arranging the light-emitting element on a circuit board by the transfer head; and detaching the transferer from the transfer head.

According to one or more embodiments, the method further includes: bonding the light-emitting element attached to the transferer onto the circuit board; and removing the transferer by peeling it from the light-emitting element bonded to the circuit board by the transfer head.

According to one or more embodiments, a method of transferring a light-emitting element includes: cutting an original sheet of a transferer into a size of a transferring portion by a cutter; forming an incision groove on a protective film to define a folding portion and the transferring portion; picking up transferers using a inverter; inverting the transferers up, down, left, and right; folding up the folding portion by adsorbing the protective film attached to the folding portion by a side chuck of a loader, and raising a vertical mover of the inverter below the folding portion in a state in which a transfer head adsorbs the transferring portion; fixing the folding portion that is folded with a clamp of the transfer head; lifting the transferer; peeling off the protective film of the transferer; picking up the light-emitting element from a donor substrate by adhering the light-emitting element to the transferer by the transfer head; detaching the clamp from the folding portion by releasing the clamp and fixing the clamp to the folding portion; arranging the light-emitting element on a circuit board by the transfer head; and detaching the transferer from the transfer head.

According to one or more embodiments, the method further includes: bonding the light-emitting element attached to the transferer onto the circuit board; and removing the transferer by peeling it from the light-emitting element bonded to the circuit board by the transfer head.

### BRIEF DESCRIPTION OF THE DRAWINGS

FIG. 1 is a layout diagram illustrating a display device according to one or more embodiments.

FIG. 2 illustrates the pixel of FIG. 1 according to one or more embodiments.

FIG. 3 illustrates the pixels of FIG. 1 according to one or more other embodiments.

FIG. 4 is a cross-sectional view illustrating a display panel cut along the line A-A′ of FIG. 2 according to one or more embodiments.

FIG. 5 illustrates a configuration of a transfer device of a light-emitting element according to one or more embodiments.

FIG. 6 is a flow diagram illustrating a method of transferring a light-emitting element performed using the above-described transfer apparatus of a light-emitting element.

FIG. 7 is a perspective view to illustrate a method for providing a transfer member ledger in a roll-to-roll manner.

FIG. 8 is a perspective view to illustrate a method of providing a transfer member ledger in a sheet-type manner.

FIGS. 9-23 are schematic diagrams illustrating the operation of a transfer device of a light-emitting element.

FIG. 24 is a schematic diagram illustrating bonding of the light-emitting element.

FIG. 25 is a schematic diagram illustrating removal of a transfer member.

FIG. 26 is a schematic diagram illustrating a circuit board on which a light-emitting element is located.

FIG. 27 is an enlarged view of an area A of FIG. 26.

FIG. 28 is a diagram illustrating a configuration of a transfer device of a light-emitting element according to one or more embodiments.

FIG. 29 is a flow diagram illustrating a method of transcribing a light-emitting element performed using the light-emitting element transcription device of FIG. 28.

FIGS. 30-34 illustrate the operation of the light-emitting element transfer device of FIG. 28.

FIGS. 35-40 illustrate a configuration of the transfer device of the light-emitting element according to one or more embodiments.

FIG. 41 illustrates a configuration of a light-emitting element transfer device according to one or more embodiments.

FIG. 42 is a flow diagram to illustrate the operation of the light-emitting element of FIG. 41.

FIGS. 43-50 illustrate the operation of the transcription device of the light-emitting element.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

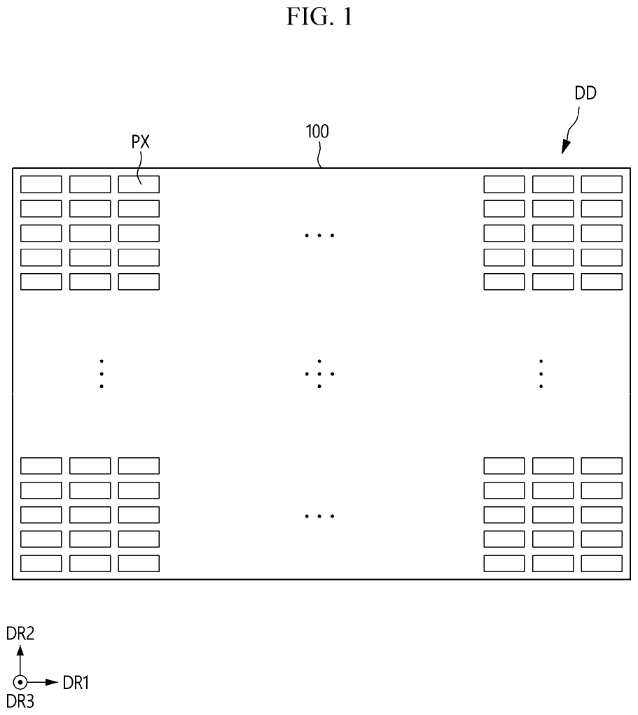

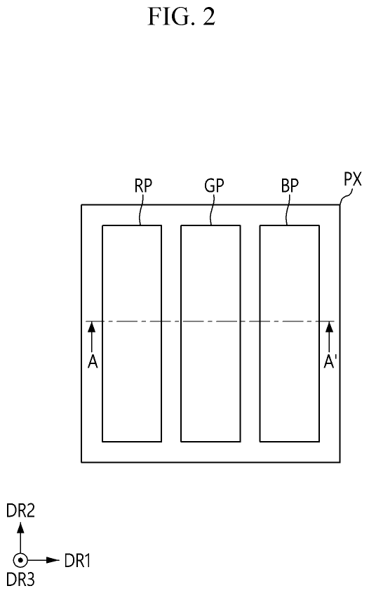

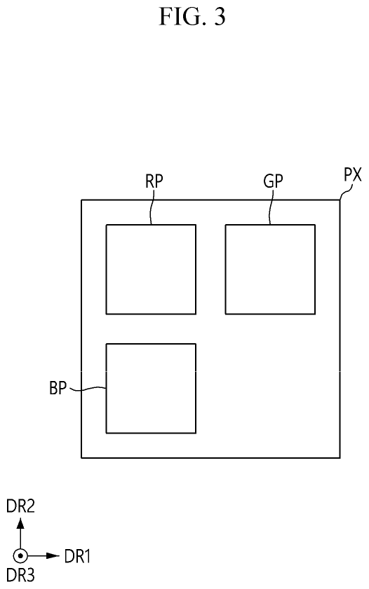

FIG. 1 is a layout diagram illustrating a display device according to one or more embodiments. FIG. 2 illustrates the pixel of FIG. 1 according to one or more embodiments. FIG. 3 illustrates the pixels of FIG. 1 according to one or more other embodiments.

Referring to FIGS. 1-3, a display device DD is a device for displaying a moving image or a still image and may be used as a display screen of various products, such as a television, a notebook computer, monitors, billboards, internet of things (IOT), etc., as well as a portable electronic device such as a mobile phone, a smart phone, a tablet personal computer (PC), a smart watch, a watch phone, a mobile communication terminal, an electronic notebook, an e-book, a portable multimedia player (PMP), navigation, Ultra Mobile PC (UMPC) and the like.

The display panel 100 may be formed as a rectangular-shaped plane with a long side in the first direction DR1 and a short side in the second direction DR2 crossing the first direction DR1. The corner where the long side of the first direction DR1 and the short side of the second direction DR2 meet may be rounded to have a suitable curvature (e.g., a predetermined curvature) or may be formed at a right angle. The planar shape of the display panel 100 is not limited to a rectangle, but may be formed into other polygons, circles, or ovals. The display panel 100 may be formed flat but is not limited thereto. For example, the display panel 100 may be formed at the left and right ends and may include curved portions having a constant curvature or a varying curvature. Additionally, the display panel 100 may be formed to be flexible, such as to be able to be bent, twisted, folded, and/or curled.

The display panel 100 may further include pixels PX, scan wires extending in the first direction DR1, and data wires extending in the second direction DR2 for displaying an image. The pixels PX may be arranged in a matrix form in the first direction DR1 and the second direction DR2. For example, the pixels PX may be arranged along rows and columns of a matrix.

Each of the pixels PX may include a plurality of sub-pixels RP, GP, and BP as shown in FIGS. 2 and 3. In FIGS. 2 and 3, each of the pixels PX includes three sub-pixels RP, GP, and BP, namely a first sub-pixel RP, a second sub-pixel GP, and a third sub-pixel BP, but embodiments of the present disclosure are not limited thereto.

The first sub-pixel RP, the second sub-pixel GP, and the third sub-pixel BP may be connected to any one of the data wires, and to at least one of the scan wires from among the scan wires.

Each of the first sub-pixel RP, the second sub-pixel GP, and the third sub-pixel BP may have the rectangular, square, or rhombus planar shape. For example, each of the first sub-pixel RP, the second sub-pixel GP, and the third sub-pixel BP may have a rectangular planar shape having a short side in the first direction DR1 and a long side in the second direction DR2 as shown in FIG. 2. Alternatively, each of the first sub-pixel RP, the second sub-pixel GP, and the third sub-pixel BP may have the planar shape of a square or rhombus with sides having equal lengths in the first direction DR1 and the second direction DR2 as shown in FIG. 3.

As shown in FIG. 2, the first sub-pixel RP, the second sub-pixel GP, and the third sub-pixel BP may be arranged in the first direction DR1. Alternatively, one of the second sub-pixel GP and the third sub-pixel BP and the first sub-pixel RP are arranged in the first direction DR1, and the other of the second sub-pixel GP and the first sub-pixel RP may be arranged in the second direction DR2. For example, as shown in FIG. 3, the first sub-pixel RP and the second sub-pixel GP may be arranged in the first direction DR1, and the first sub-pixel RP and the third sub-pixel BP may be arranged in the second direction DR2.

Alternatively, one of the first sub-pixel RP and the third sub-pixel BP and the second sub-pixel GP may be arranged in the first direction DR1, and the other of the first sub-pixel RP and the second sub-pixel GP may be arranged in the second direction DR2. Alternatively, one of the first sub-pixel RP and the second sub-pixel GP and the third sub-pixel BP may be arranged in the first direction DR1, and the other one and the third sub-pixel BP may be arranged in the second direction DR2.

The first sub-pixel RP may include a first light-emitting element that emits a first light, the second sub-pixel GP may include a second light-emitting element that emits a second light, and the third sub-pixel BP may include a third light-emitting element that emits a third light. Here, the first light may be light in a red wavelength band, the second light may be light in a green wavelength band, and the third light may be light in a blue wavelength band. The red wavelength band may be a wavelength band of about 600 μm to about 750 μm, the green wavelength band may be a wavelength band of about 480 μm to about 560 μm, and the blue wavelength band may be a wavelength band of about 370 μm to about 460 μm, but the present disclosure is not limited thereto.

Each of the first sub-pixel RP, the second sub-pixel GP, and the third sub-pixel BP may include an inorganic light-emitting element having an inorganic semiconductor as the light-emitting element that emits light. For example, the inorganic light-emitting element may be a flip chip type micro light-emitting diode (LED), but the present disclosure is not limited thereto.

As shown in FIGS. 2 and 3, the area of the first sub-pixel RP, the area of the second sub-pixel GP, and the area of the third sub-pixel BP may be substantially the same, but the present disclosure is not limited thereto. At least one of the areas of the first sub-pixel RP, the area of the second sub-pixel GP, and the area of the third sub-pixel BP may be different from the other. Alternatively, any two of the areas of the first sub-pixel RP, the area of the second sub-pixel GP, and the area of the third sub-pixel BP may be substantially the same, and the other may be different from the above two. Alternatively, the area of the first sub-pixel RP, the area of the second sub-pixel GP, and the area of the third sub-pixel BP may be different from each other.

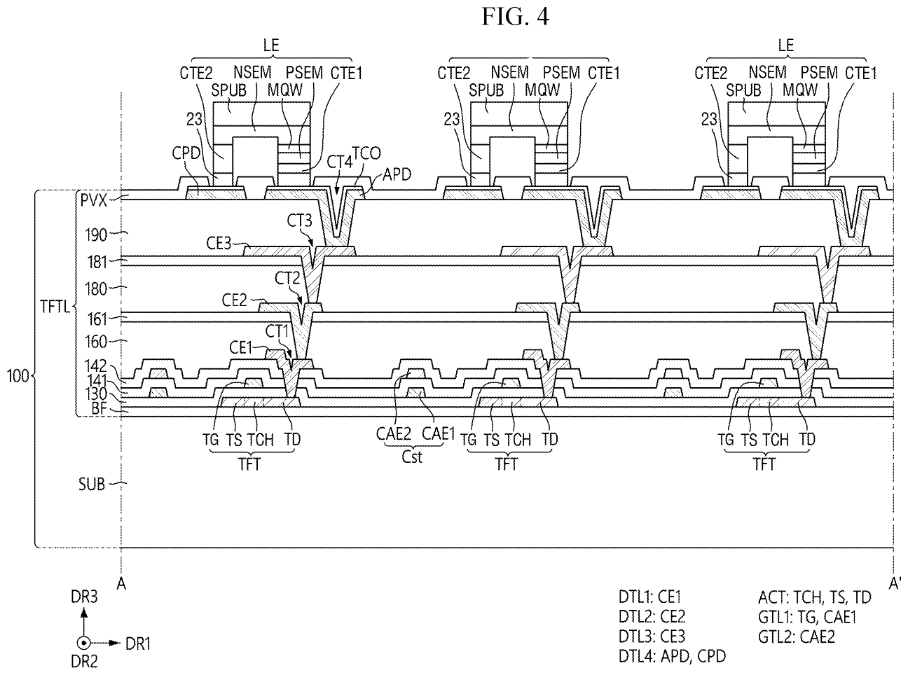

FIG. 4 is a cross-sectional view illustrating one example of a display panel cut along the line A-A′ of FIG. 2.

Referring to FIG. 4, the display panel 100 may include a thin film transistor layer TFTL and light-emitting elements LE located on a substrate SUB. The thin film transistor layer TFTL may be a layer in which thin film transistors TFT are formed.

The thin film transistor layer TFTL may include an active layer ACT, a first gate layer GTL1, a second gate layer GTL2, a first data metal layer DTL1, a second data metal layer DTL2, a third data metal layer DTL3, and a fourth data metal layer DTL4. Further, the thin film transistor layer TFTL includes a buffer film BF, a gate insulation film 130, a first interlayer insulation film 141, a second interlayer insulation film 142, a first planarization film 160, a first insulation film 161, a second planarization film 180, a second insulation film 181, a third planarization film 190, and a protective film PVX.

The substrate SUB may be a base substrate or base member for supporting the display device. The substrate SUB may be a rigid substrate made of glass, but the present disclosure is not limited thereto. The substrate SUB may be a flexible substrate that may be bent, folded, rolled, and/or the like. In this case, the substrate may include an insulating material such as a polymeric resin such as polyimide PI.

The buffer film BF may be located on one side of the substrate SUB. The buffer film BF may be a film for reducing or preventing the penetration of air or moisture. The buffer film BF may include a plurality of inorganic films stacked in alternating layers. For example, the buffer film may be formed as a plurality of alternately stacked inorganic films of one or more of a silicon nitride layer, a silicon oxynitride layer, a silicon oxide layer, a titanium oxide layer, and an aluminum oxide layer. The buffer film BF may be omitted.

The active layer ACT may be located on the buffer film BF. The active layer ACT may include a silicon semiconductor, such as polycrystalline silicon, single crystal silicon, low temperature polycrystalline silicon, and amorphous silicon, or may include an oxide semiconductor.

The active layer ACT may include a channel TCH of a thin film transistor TFT, a first electrode TS, and a second electrode TD. The channel TCH of the thin film transistor TFT may be a region that overlaps with the gate electrode TG of the thin film transistor TFT in the third direction DR3, which is the thickness direction of the substrate SUB. The first electrode TS of the thin film transistor TFT may be located on one side of the channel TCH, and the second electrode TD may be located on the other side of the channel TCH. The first electrode TS and the second electrode TD of the thin film transistor TFT may be regions that do not overlap with the gate electrode TG in the third direction DR3. The first electrode TS and the second electrode TD of the thin film transistor TFT may be regions in which a silicon semiconductor or an oxide semiconductor is doped with ions to make it conductive.

The gate insulation film 130 may be located on the active layer ACT and the buffer layer BF. The gate insulation film 130 may be formed of an inorganic film, such as a silicon nitride layer, a silicon oxynitride layer, a silicon oxide layer, a titanium oxide layer, or an aluminum oxide layer.

The first gate layer GTL1 may be located on the gate insulation film 130. The first gate layer GTL1 may include a gate electrode TG of a thin film transistor TFT and a first capacitor electrode CAE1. The first gate layer GTL1 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

A first interlayer insulation film 141 may be located on the first gate layer GTL1 and the gate insulation film 130. The first interlayer insulation film 141 may be formed of an inorganic film, such as a silicon nitride layer, a silicon oxynitride layer, a silicon oxide layer, a titanium oxide layer, or an aluminum oxide layer.

The second gate layer GTL2 may be located on the first interlayer insulation film 141. The second gate layer GTL2 may include a second capacitor electrode CAE2. The second gate layer GTL2 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

The second interlayer insulation film 142 may be located on the second gate layer GTL2 and the first interlayer insulation film 141. The second interlayer insulation film 142 may be formed of an inorganic film, such as a silicon nitride layer, a silicon oxynitride layer, a silicon oxide layer, a titanium oxide layer, and/or an aluminum oxide layer.

The first data metal layer DTL1 including a first connection electrode CE1, a first sub-pad, and data line may be located on the second interlayer insulation film 142. The data line may be integrally formed with the first sub-pad, but the present disclosure is not limited thereto. The first data metal layer DTL1 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

The first connection electrode CE1 may be connected to the first electrode TS or the second electrode TD of a thin film transistor TFT through a first contact hole CT1 penetrating and the gate insulation film 130, the first interlayer insulation film 141, and the second interlayer insulation film 142.

The first planarization film 160 may be located to flatten a step caused by the active layer ACT, the first gate layer GTL1, the second gate layer GTL2, and the first data metal layer DTL1, on the first data metal layer DTL1 and the second interlayer insulation film 142. The first planarization film 160 may be formed from an organic film such as an acrylic resin, an epoxy resin, a phenolic resin, a polyamide resin, a polyimide resin, and/or the like.

A first insulation film 161 may be located on the first planarization film 160. The second data metal layer DTL2 may be located on the first planarization film 160 and the first insulation film 161. The second data metal layer DTL2 may include a second connection electrode CE2 and a second sub-pad. The second connection electrode CE2 may be connected to the first connection electrode CE1 through a second contact hole CT2 penetrating the first insulation film 161 and the first planarization film 160. The second data metal layer DTL2 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

The second planarization film 180 may be located on top of the second data metal layer DTL2 and the first insulation film 161. The second planarization film 180 may be formed of an organic film such as an acrylic resin, an epoxy resin, a phenolic resin, a polyamide resin, a polyimide resin, and/or the like.

The second insulation film 181 may be located on the second planarization film 180. The third data metal layer DTL3 may be located on the second planarization film 180 and the second insulation film 181. The third data metal layer DTL3 may include a third connection electrode CE3 and a third sub pad. The third connection electrode CE3 may be connected to the second connection electrode CE2 through a third contact hole CT3 penetrating the second insulation film 181 and the second planarization film 180. The third data metal layer DTL3 may be formed as a single layer or multiple layers of one of molybdenum (Mo), aluminum (Al), chromium (Cr), gold (Au), titanium (Ti), nickel (Ni), neodymium (Nd), and/or copper (Cu), and/or an alloy thereof.

The third planarization film 190 may be located on top of the third data metal layer DTL3 and the second insulation film 181. The third planarization film 190 may be formed of an organic film, such as an acrylic resin, an epoxy resin, a phenolic resin, a polyamide resin, a polyimide resin, and/or the like.

The fourth data metal layer DTL4 may be located on the third planarization film 190. The fourth data metal layer DTL4 may include an anode pad electrode APD, a cathode pad electrode CPD, and a fourth sub pad. The anode pad electrode APD may be connected to the third connection electrode CE3 through a fourth contact hole CT4 penetrating the third planarization film 190. The cathode pad electrode CPD may be supplied with a first power supply voltage that is a low potential voltage. The fourth data metal layer DTL4 may be formed as a single layer or multiple layers of one of molybdenum (Mo), aluminum (Al), chromium (Cr), gold (Au), titanium (Ti), nickel (Ni), neodymium (Nd), and/or copper (Cu), or an alloy thereof.

A transparent conductive layer TCO may be located to increase adhesion with a first contact electrode CTE1 and a second contact electrode CTE2 of the light-emitting element LE on each of the anode pad electrode APD and cathode pad electrode CPD. The transparent conductive layer TCO and a fifth sub-pad may be formed of a transparent conductive oxide, such as indium tin oxide (ITO) and/or indium zinc oxide (IZO).

A protective film PVX may be located on the anode pad electrode APD, cathode pad electrode CPD, and a first pad. The protective film PVX may be located to cover the edges of the anode pad electrode APD, the cathode pad electrode CPD, and the first pad. The protective film PVX may be formed of an inorganic film, such as a silicon nitride layer, a silicon oxynitride layer, a silicon oxide layer, a titanium oxide layer, and/or an aluminum oxide layer. In one or more embodiments, the protective film PVX may be omitted.

The light-emitting element LE is illustrated as a flip-chip type micro LED in which the first contact electrode CTE1 and the second contact electrode CTE2 are located opposite the anode pad electrode APD and the cathode pad electrode CPD. The light-emitting element LE may be the inorganic light-emitting element made of an inorganic material such as GaN. The light-emitting element LE may have a length in the first direction DR1, a length in the second direction DR2, and a length in the third direction DR3 of several to several hundred μm each. For example, the light-emitting element LE may have the length in the first direction DR1, the length in the second direction DR2, and the length in the third direction DR3 of about 100 μm or less.

The light-emitting elements LE may be formed by growth on a semiconductor substrate such as a silicon wafer. Each of the light-emitting elements LE may be transferred directly from the silicon wafer onto the anode pad electrode APD and the cathode pad electrode CPD of the substrate SUB. In this case, the first contact electrode CTE1 and the anode pad electrode APD may be bonded together through a bonding process. Additionally, the second contact electrode CTE2 and the cathode pad electrode CPD may be bonded to each other through the bonding process. The first contact electrode CTE1 and the anode pad electrode APD may be electrically connected to each other through a bonding electrode 23. Further, the second contact electrode CTE2 and the cathode pad electrode CPD may be electrically connected to each other through the bonding electrode 23.

For example, the bonding electrode 23 may be located on one side of the light-emitting element LE. The bonding electrode 23 may be a bonding material of a pressurized melt bonding using a laser. Here, the pressurized melt bonding refers to a state in which the bonding electrode 23 is melted under heat to melt and mix the light-emitting element LE, the anode pad electrode APD, and the cathode pad electrode CPD, and is cooled and solidified when the laser supply is terminated. The conductivity of the light-emitting element LE and the anode pad electrode APD and the cathode pad electrode CPD is maintained while being cooled and solidified from the molten mixed state. Thus, the anode pad electrode APD and cathode pad electrode CPD and the light-emitting element LE may be electrically connected and physically connected respectively. Therefore, the bonding electrode 23 may be located on the first contact electrode CTE1 and the second contact electrode CTE2 of the light-emitting element LE.

The bonding electrode 23 may include, for example, Au, AuSn, PdIn, InSn, NiSn, Au—Au, AgIn, AgSn, Al, Ag, and/or carbon nanotubes (CNT). Each of these may be utilized alone or in combination with two or more. Depending on the type of bonding electrode 23, the bonding electrode 23 may be formed by deposition on the pad electrode or may be formed on the pad electrode by various methods such as screen printing.

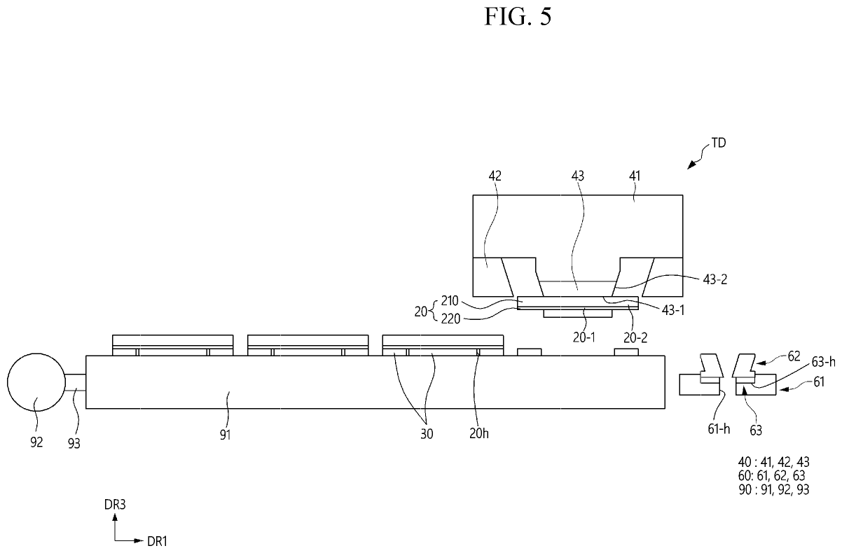

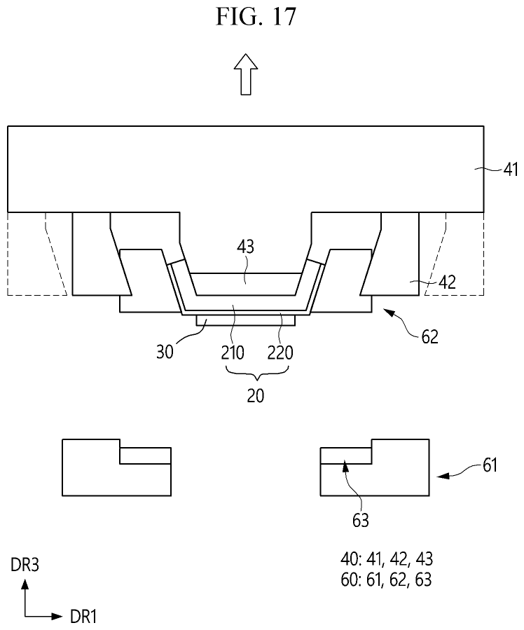

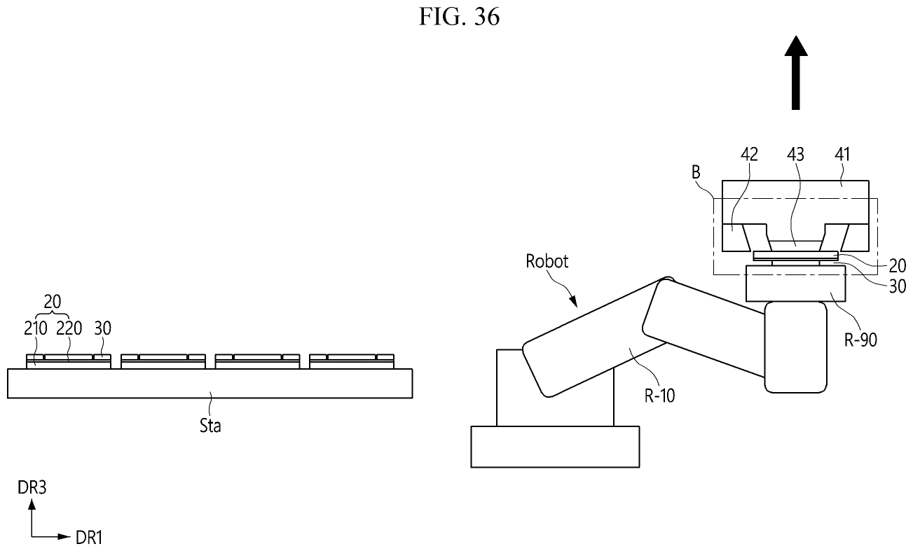

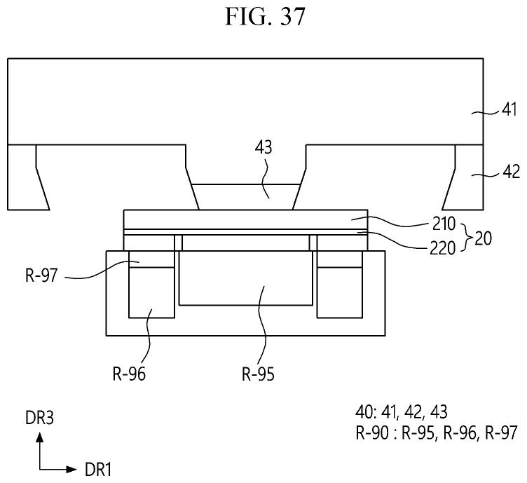

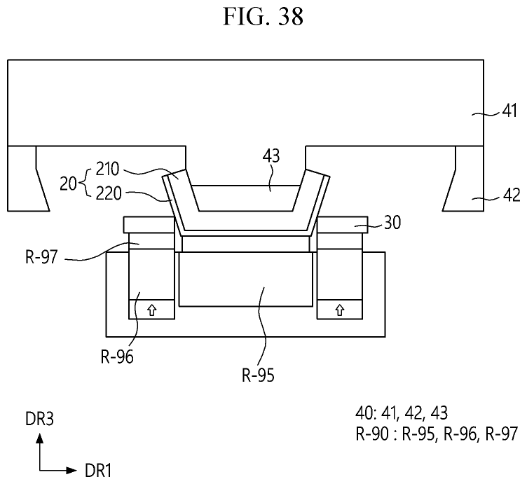

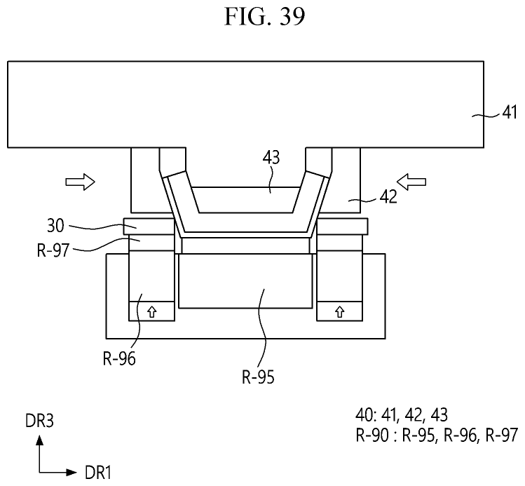

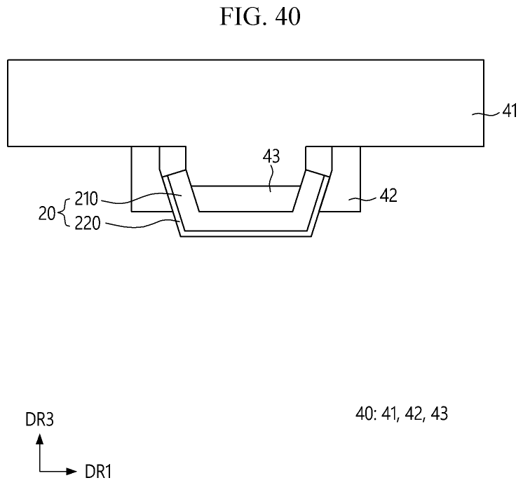

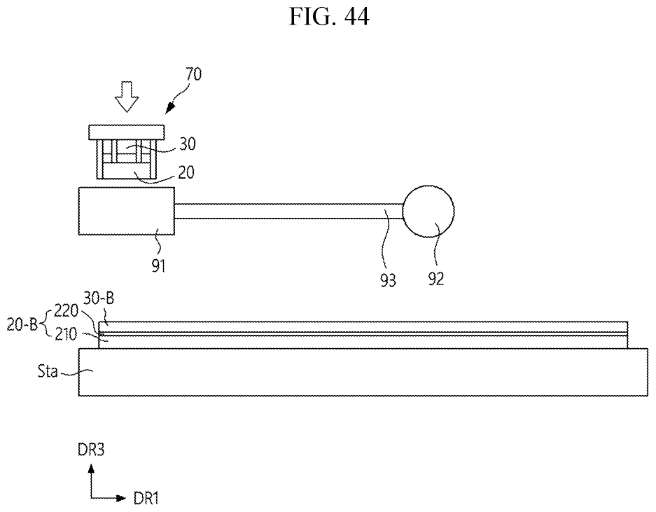

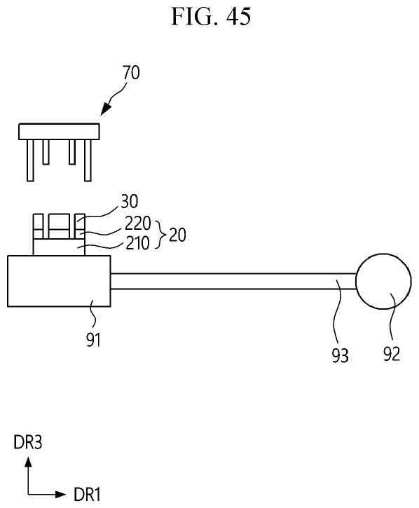

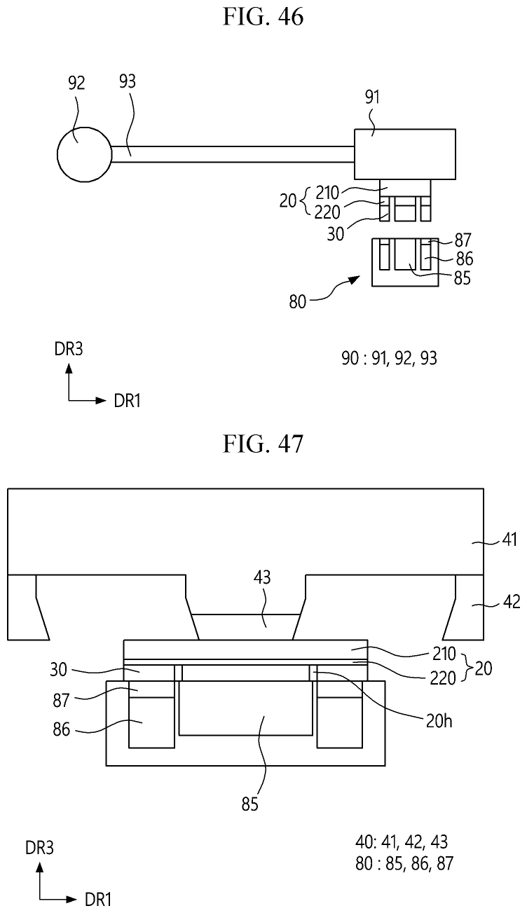

Alternatively, each of the light-emitting elements LE may be transferred onto the anode pad electrode APD and the cathode pad electrode CPD of the substrate SUB using a transfer member (e.g., a transferer). This will be described below with reference to FIGS. 5-50.

Each of the light-emitting elements LE may be a light-emitting structure including a base substrate SPUB, an n-type semiconductor NSEM, an active layer MQW, a p-type semiconductor PSEM, a first contact electrode CTE1, and a second contact electrode CTE2.

The base substrate SPUB may be a sapphire substrate, but the present disclosure is not limited thereto.

The n-type semiconductor NSEM may be located on one side of the base substrate SPUB. For example, the n-type semiconductor NSEM may be located on a bottom surface of the base substrate SPUB. The n-type semiconductor NSEM may include GaN doped with n-type conductive dopants such as Si, Ge, Sn, and/or the like.

The active layer MQW may be located on a portion of one side of an n-type semiconductor NSEM. The active layer MQW may include material with a single or multiple quantum well structure. If the MQW includes a material with a multi-quantum well structure, it may be a stacked structure with a plurality of well layers and barrier layers alternating with each other. In this case, the well layer may be formed of InGaN and the barrier layer may be formed of GaN and/or AlGaN, but is not limited thereto. Alternatively, the active layer MQW may be a structure in which a semiconductor material with a large band gap energy and a semiconductor material with a small band gap energy are alternately stacked on top of each other, or may include three or five different semiconductor materials depending on the wavelength of the light to be emitted.

Hereinafter, the transfer device of the light-emitting element and an operating method thereof according to one or more embodiments will be described with reference to FIGS. 5-27.

FIG. 5 is a drawing to illustrate a configuration of a transfer device of a light-emitting element according to one or more embodiments.

Referring to FIG. 5, the transfer device TD of a light-emitting element according to one or more embodiments may include a transfer member (e.g., a transferer) 20, a protective film 30, an inversion member (e.g., an inverter) 90, a transfer head 40, and a folding member (e.g., a folder) 60.

The transfer member 20 includes a stamp layer 220 having a tacky or adhesive property, and a base layer 210 located on one side of the stamped layer.

The base layer 210 may comprise, for example, glass and/or plastic. If the protective film 30 includes a thin glass, the glass may be an ultra-thin tempered glass. Alternatively, the base layer 210 may include polyethylene terephthalate (PET), polyurethane (PU), polyimide (PI), polycarbonate (PC), polyethylene (PE), polypropylene (PP), polysulfone (PSF), polymethyl methacrylate (PMMA), triacetyl cellulose (TAC), cycloolefin polymer (COP), and/or the like.

The stamp layer 220 is located on one side of the base layer 210. The stamp layer 220 may be adhered or bonded to the light-emitting element LE. The stamp layer 220 may include an adhesive or tacky material, for example, an optical clear adhesive (OCA), a pressure sensitive adhesive (PSA), and/or the like, and the tacky material may include, for example, an acrylic-based, urethane-based, and/or silicone-based adhesive material. The stamp layer 220 may be formed with a thickness that is less than the thickness of the base layer 210.

The transfer member 20 may include a transfer unit (e.g., a transferring portion) 20-1 and a folding unit (e.g., a folding portion) 20-2 in a plan view. The transfer unit 20-1 may be formed at a center with an incision groove 20h as the boundary, and the folding unit 20-2 may be formed at an edge with the incision groove 20h as the boundary.

The protective film 30 may be attached to a first side of the transfer member 20, and a transfer head 40 may be adsorbed on the other side of the transfer member 20. The protective film 30 may be attached to a first side of the stamp layer 220 of the transfer member 20 to reduce or prevent contaminants adhering to the stamp layer 220.

The protective film 30 is located on the other side of the stamp layer 220 of the transfer member 20 to prevent contamination of the stamp layer 220. The protective film 30 may comprise, for example, glass or plastic. If the protective film 30 includes a thin glass, the glass may be the ultra-thin tempered glass.

The inversion member 90 inverts the top and bottom of the transfer member 20.

The inversion member 90 may include a stage 91, a rotation shaft 92, and a connection 93 connecting the stage 91 and the rotation shaft 92. The stage 91 may be rotated about 180 degrees about the rotation shaft 92. The stage 91 may include a plurality of chucks. The plurality of chucks may be any one of an electrostatic chuck, an adhesive chuck, a vacuum chuck, or a porous vacuum chuck. The stage 91 may utilize the plurality of chucks to adsorb a first side of the protective film 30.

The inversion member 90 utilizes the chuck to remove the protective film 30 of the folding unit 20-2 of the transfer member 20.

The transfer head 40 has a head chuck 43 that is adsorbed on the base layer 210 of the transfer member 20 and is movable up, down, left, and right.

The transfer head 40 may include a body unit (e.g., a body) 41, a first clamp 42, and a head chuck 43.

The head chuck 43 may be located at a center of a movement unit of one side of the body unit 41. The head chuck 43 may be capable of attaching and detaching the transfer member 20 through a chuck function. For example, the head chuck 43 may include a chuck of any one of the electrostatic chuck, the adhesive chuck, the vacuum chuck, or the porous vacuum chuck.

The head chuck 43 may include a center unit (e.g., a central portion) 43-1 and an inclined unit (e.g., inclined portion) 43-2. The central unit 43-1 is located in the center of the head chuck 43, and the inclined unit 43-2 is located around the perimeter of the central unit 43-1. The inclined unit 43-2 may have a different inclination than the central unit 43-1. As will be described later, the folding unit 20-2 of the transfer member 20 may be folded along the inclination of the inclined unit 43-2 of the head chuck 43.

When the transfer member 20 is attached to the head chuck 43, the transfer unit 20-1 of the transfer member 20 is attached to the center unit 43-1 and the folding unit 20-2 is attached to the inclined unit 43-2.

The first clamp 42 is located adjacent to the head chuck 43 on a first side of the body unit 41 and is movably located in a horizontal direction. The first clamp 42 is moveable in the horizontal direction to move closer or further away from the head chuck 43. The first clamp 42 is located to wrap around at least a portion of the outer peripheral surface of the head chuck 43 and may be symmetrically located from side to side. For movement of the first clamp 42, the transfer head 40 may comprise, for example, a guide rail to guide the first clamp 42 in the horizontal direction but is not limited thereto.

The folding member 60 folds the folding unit 20-2 of the transfer member 20 attached to the head chuck 43. When the folding unit 20-2 of the transfer member 20 attached to the head chuck 43 is folded, the folding unit 20-2 may contact the inclined unit 43-2 of the head chuck 43.

The folding member 60 includes a second clamp 62, which may be removable. The folding member 60 may include a clamp support unit (e.g., a clamp support) 61, a clamp fixture 63, and a second clamp 62 removably attached to the clamp fixture 63.

The clamp support unit 61 may include a first groove 61-h in the center, and a second groove 63-h in a region adjacent to the first groove 61-h. The clamp fixture 63 is located in the second groove 63-h. The clamp fixture 63 is located around the first groove 61-h, which is a center groove. The second clamp 62 is located on the clamp fixture 63. The second clamp 62 is removably formed on the clamp fixture 63. For example, the clamp fixture 63 may have a chuck on one side. The chuck may be any one of the electrostatic chuck, the adhesive chuck, the vacuum chuck, and/or the porous vacuum chuck. The clamp fixture 63 may be removable from the second clamp 62 by the suction capability of the chuck. In one or more embodiments, the clamp fixture 63 and the second clamp 62 may be made removable from each other by including a magnet.

The second clamps 62 are formed to correspond in size and shape to the folds 20-2 of the transfer member 20. The second clamp 62 may be formed as a plurality of separate units. The plurality of units may each be formed to be moveable in a plane.

For example, the transfer unit 20-1 may be formed as a square, and the folding unit 20-2 may be formed as four rectangular units located around the perimeter of the transfer unit 20-1. In such a case, the second clamp 62 may also be formed as four separate units corresponding to the folding unit 20-2. In another variation, the transfer unit 20-1 may be formed in a circular shape and the folding unit 20-2 may be formed in a donut shape surrounding the transfer unit 20-1. In such a case, the second clamp 62 may also be formed in a donut shape, but as a plurality of separate units.

The second clamp 62 may be attached to the clamp fixture 63 to guide the transfer member 20 into the first groove 61-h. The second clamp 62 may be formed as a structure in which each of the plurality of units is inclined toward the first groove 61-h to guide the transfer member 20 into the first groove 61-h, so that the second clamp 62 becomes narrower toward the bottom.

When the second clamp 62 is formed from a plurality of divided units, the second clamp 62 may further comprise a movement guide. The plurality of units may each be movably formed by the movement guide. The movement guide may comprise, for example, a guide rail along which the plurality of units may slide.

The second clamp 62 secures the folding unit 20-2 of the transfer member 20 to maintain the folding state.

Each of the detailed components of the transfer device TD of the light-emitting element and the operation method of the transfer device TD of the light-emitting element will be described in detail with reference to the following drawings.

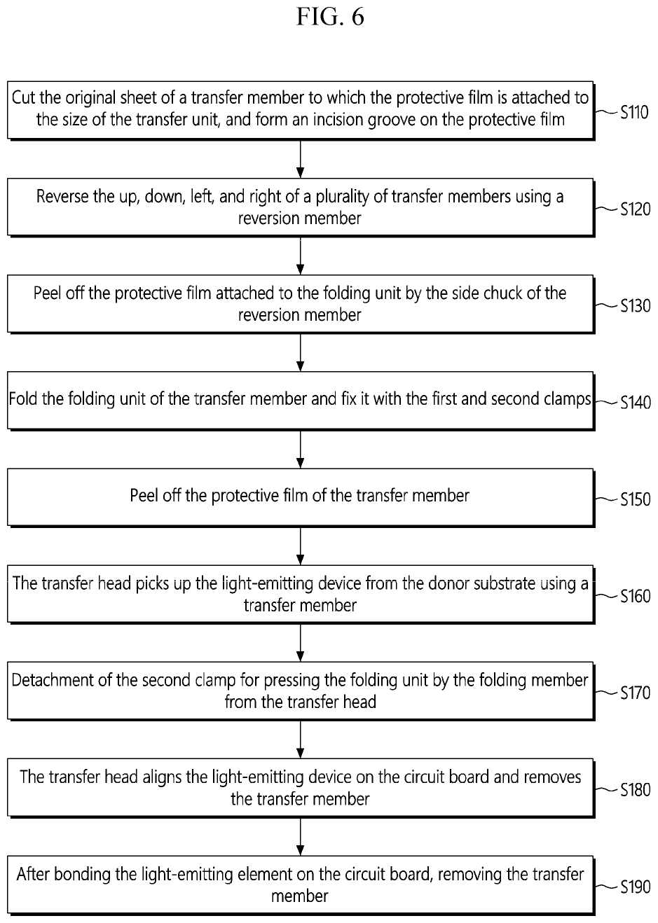

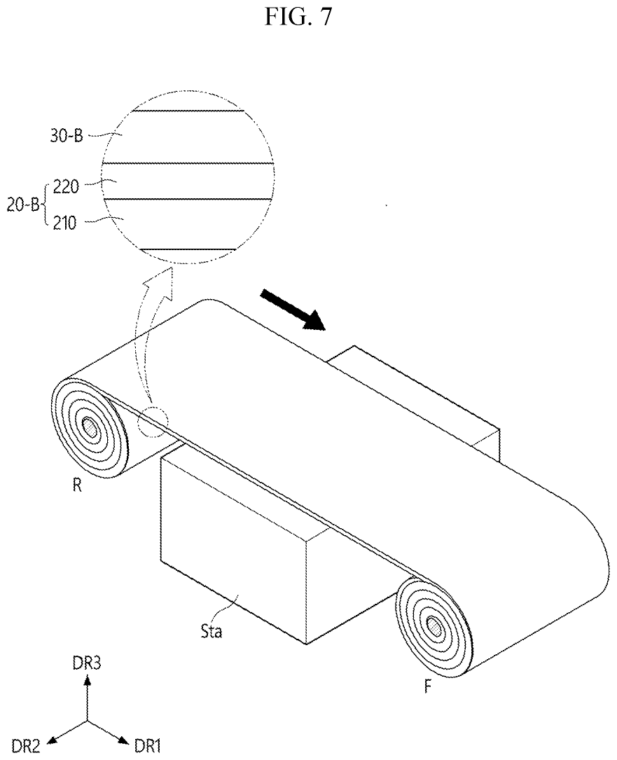

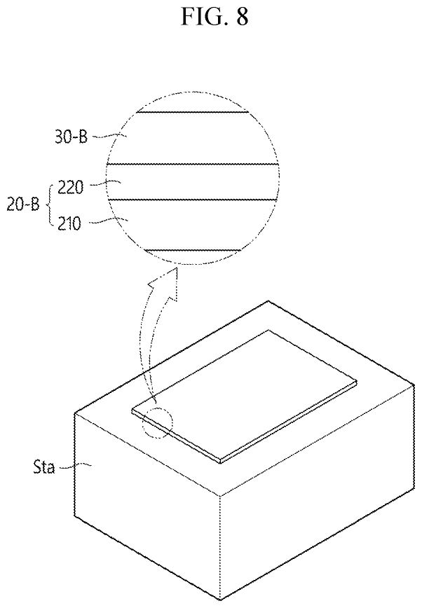

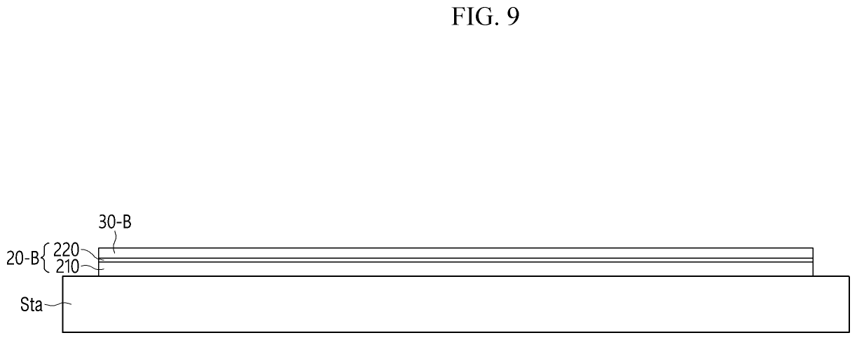

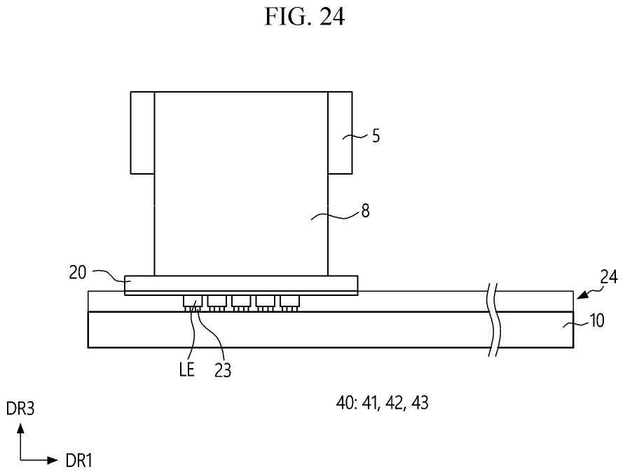

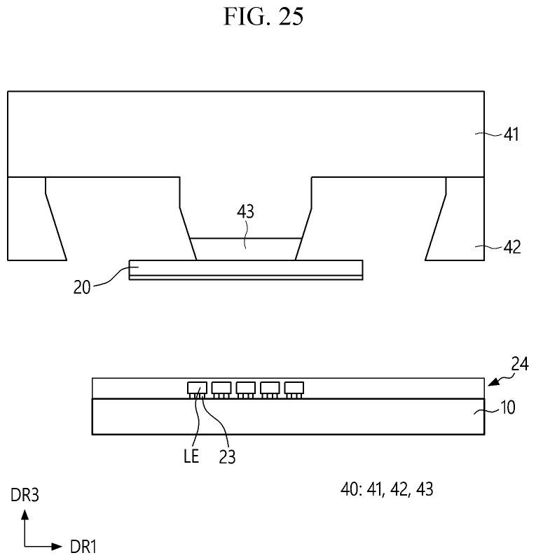

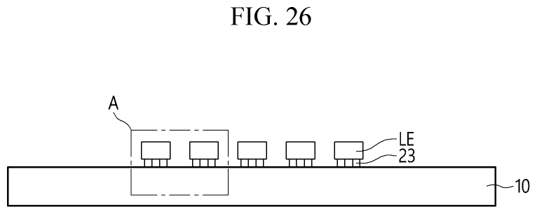

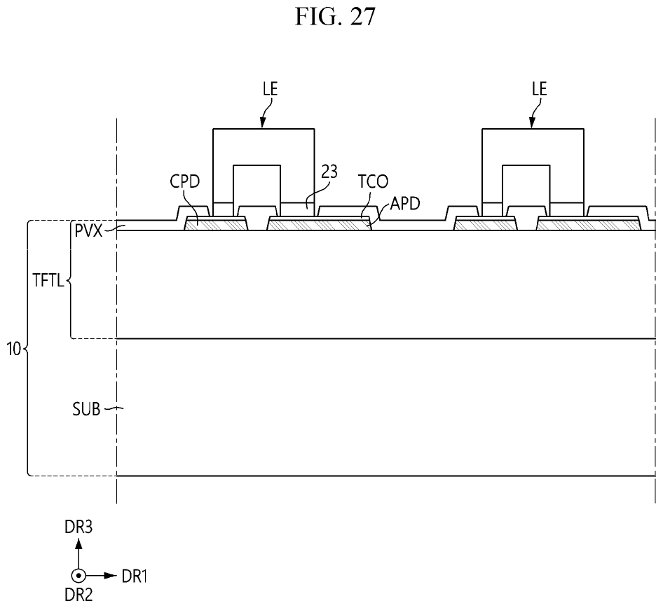

FIG. 6 is a flow diagram illustrating a method of transferring a light-emitting element performed using the above-described transfer apparatus of a light-emitting element. FIG. 7 is a perspective view to illustrate a method for providing a transfer member ledger in a roll-to-roll manner. FIG. 8 is a perspective view to illustrate a method of providing a transfer member ledger in a sheet-type manner. FIGS. 9-23 are schematic diagrams illustrating the operation of a transfer device of a light-emitting element. FIG. 24 is a schematic diagram illustrating bonding of the light-emitting element. FIG. 25 is a schematic diagram illustrating removal of a transfer member. FIG. 26 is a schematic diagram illustrating a circuit board on which a light-emitting element is located. FIG. 27 is an enlarged view of an area A of FIG. 26.

Hereinafter, the flowchart of FIG. 6 will be described with reference to the drawings of FIGS. 7-27.

First, referring to FIGS. 6 and 9, a ledger of a transfer member with a protective film is cut to a transfer unit size, and an incision groove 20h is formed on the protective film. (Operation S10 of FIG. 6)

The ledger of the transfer member with the protective film is located on a support member (e.g., a support) Sta.

Here, the support member Sta serves to support the plurality of transfer members 20. The plurality of transfer members 20 may be arranged aligned on the support member Sta.

As shown in FIG. 7, a transfer member ledger 20-B may be a reel-to-reel type wound in a roll. If the transfer member ledger 20-B is provided in a reel-to-reel method, the transfer member ledger 20-B may be cut to a desired width. The ledger 20-B of the transfer member may include the base layer 210 and the stamp layer 220 located on a first side of the base layer 210 and may further include a ledger of a protective film 30-B located on the first side of the stamp layer 220.

Further, as shown in FIG. 8, the ledger 20-B of the transfer member and the protective film 30-B may be a sheet type. The sheet type differs from the reel-to-reel delivery method in that it is cut to a suitable width (e.g., a predetermined width) before being located on the support member Sta.

Referring to FIG. 9, the ledger 20-B of the transfer member to which the ledger 30-B of the protective film is attached is arranged by sequentially stacking the base layer 210, the stamp layer 220, and the protective film 30-B from the support member Sta. The base layer 210 is in contact with the support member Sta on one side and the stamp layer 220 on the other side, and the stamp layer 220 is in contact with the base layer 210 on one side and the protective film 30-B on the other side.

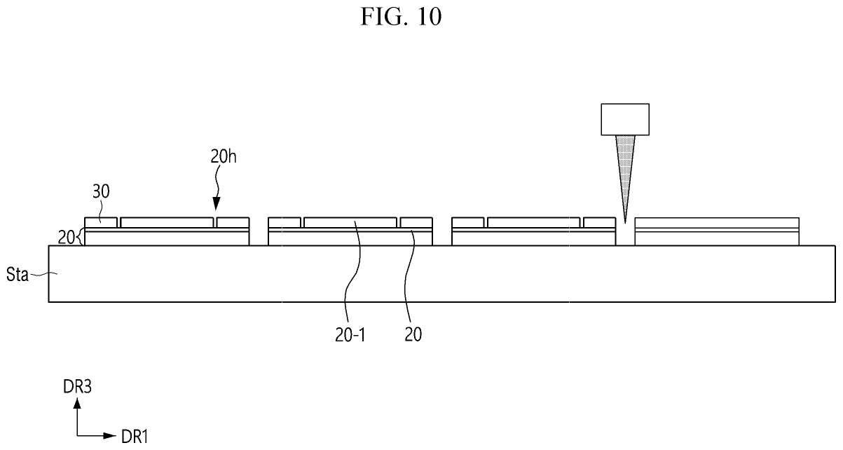

Referring to FIG. 10, the ledger 20-B of the transfer member to which the protective film 30-B is attached is cut into transfer unit sizes on the support member Sta, and an incision groove 20h is formed on the protective film 30 cut into each transfer unit. At this time, the cutting and incision may use a conventionally known cutting method, such as a mechanical method or a laser method. The transfer unit size refers to the size of a one-time transfer to a circuit board.

The incision groove 20h is formed in the protective film 30 in the direction of the base layer 210, and the incision groove 20h has a depth at least equal to or greater than the thickness of the protective film 30. For example, the incision groove 20h may be formed to penetrate the protective film 30 and the stamp layer 220. Alternatively, the incision groove 20h may be formed to penetrate the protective film 30. The incision groove 20h may not be formed in the stamp layer 220 and the base layer 210. Alternatively, the incision groove 20h may be formed in a portion of the stamp layer 220 that penetrates the protective film 30. The incision groove 20h may not be formed in the base layer 210. Alternatively, the incision groove 20h may penetrate the protective film 30 and the stamp layer 220 and may be formed in a portion of the base layer 210.

As such, the incision groove 20h is formed to at least penetrate the protective film 30 and may be formed in a portion of the transfer member 20 but is not formed to penetrate the entire transfer member 20.

The transfer member 20 may include the transfer unit 20-1 and the folding unit 20-2 bounded by the incision groove 20h.

Next, the one or more transfer members 20 are picked up using the inversion member 90 to invert upright to downright. (Operation S120 of FIG. 6)

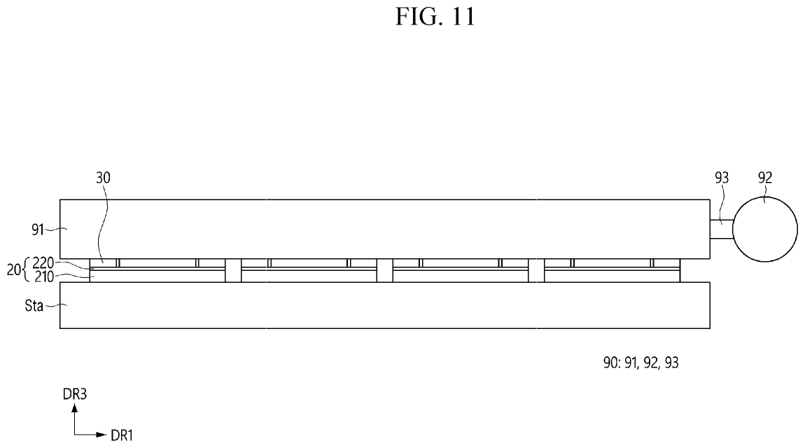

Referring to FIG. 11, in one or more embodiments, the inversion member 90 may adsorb a first side of the protective film 30 attached to the one or more transfer members 20 aligned with the support member Sta.

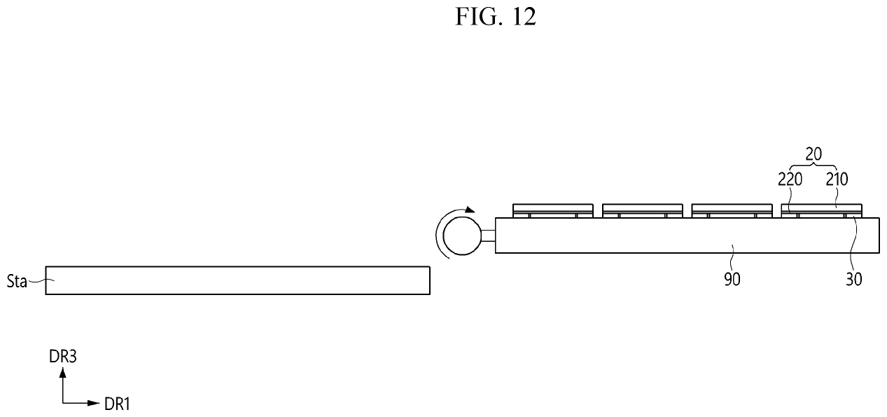

Referring to FIG. 12, while the inversion member 90 has adsorbed one side of the protective film 30, it may be rotated about 180 degrees to invert the transfer member 20 to which the protective film 30 is attached up and down and left and right. Thereby, the transfer member 20 may have the protective film 30, the stamp layer 220, and the base layer 210 arranged in order from the inversion member 90.

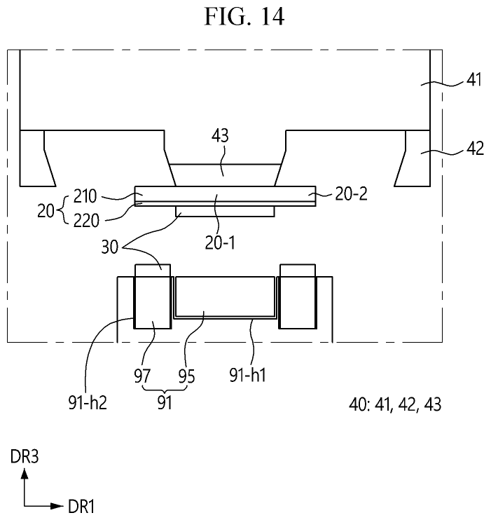

Before describing the following operations, referring to FIG. 14, a stage 91 of the inversion member 90, which is a transfer device of the light-emitting element, will be described.

The stage 91 may include a support chuck 95, and a side chuck 97. The stage 91 supports the transfer member 20, and the stage 91 may have a plurality of grooves 91-h1, 91-h2. Also, the support chucks 95 and the side chucks 97 may be embedded and located within the plurality of grooves 91-h1, 91-h2.

The support chuck 95 may be located in a first groove 91-h1 formed in a central portion of the stage 91, and the side chuck 97 may be located in the second groove 91-h2 located adjacent to the first groove 91-h1. The inversion member 90 may adsorb the protective film 30 through the support chucks 95 and side chucks 97 when it picks up the one or more transfer members 20 and inverts them upside down.

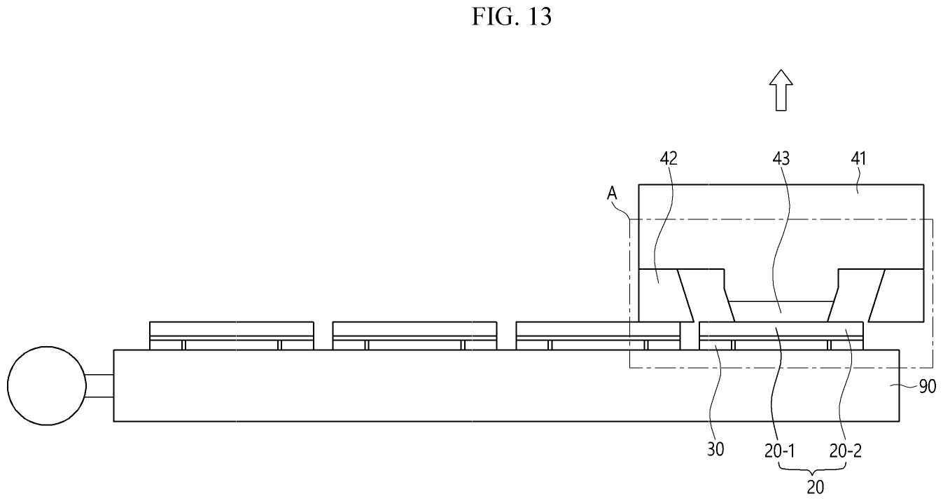

Next, referring to FIGS. 13 and 14, the protective film 30 attached to the folding unit 20-2 is peeled off by the side chuck 97 of the inversion member 90. (Operation S130 of FIG. 6)

The head chuck 43 of the transfer head 40 is arranged to overlap the transfer unit 20-1 of the transfer member 20 and not overlap the folding unit 20-2. The head chuck 43 adsorbs one side of the base layer 210 of the transfer member 20 by utilizing the adsorption function of the chuck. Next, the side chuck 97 of the inversion member 90 maintains the adsorption function while the support chuck 95 releases the adsorption function. Then, when the transfer head 40 is raised in the third direction, the transfer member 20 is adsorbed by the transfer head 40 and rises with the transfer head 40. However, because the adsorption function of the side chuck 97 is maintained, the protective film 30 of the folding unit 20-2 is peeled off from the transfer member 20 according to an adsorption force of the side chuck 97. For this purpose, the side chuck 97 must adsorb the protective film 30 with the adsorption force that is better than an adhesion force between the protective film 30 and the stamp layer 220 of the folding unit 20-2, and the head chuck 43 of the transfer head 40 must adsorb the transfer member 20 with the adsorption force that is better than the adsorption force of the side chuck 97.

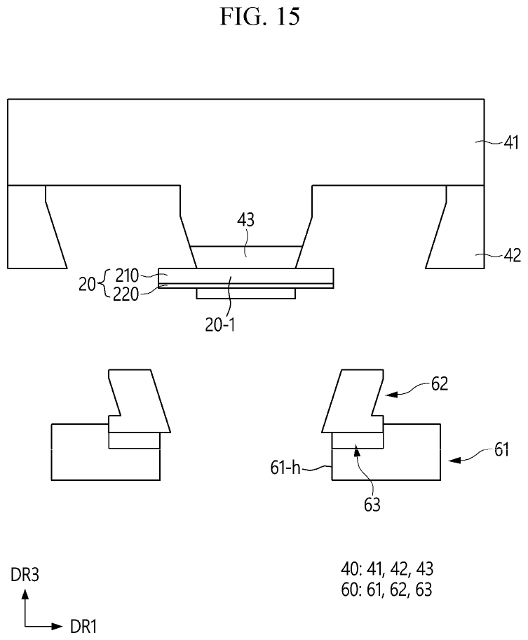

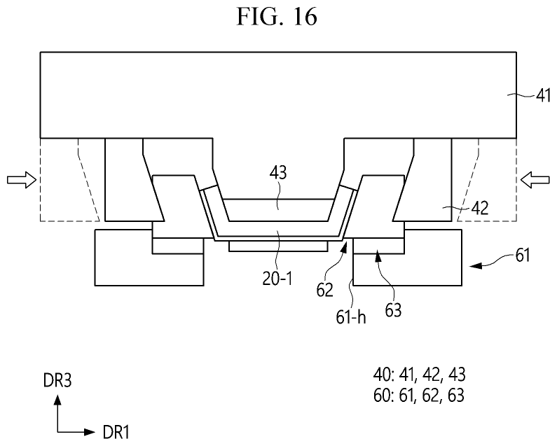

Next, as shown in FIGS. 15 and 16, the folding unit 20-2 of the transfer member is folded and secured with the first clamp 42 and the second clamp 62. (Operation S140 of FIG. 6)

The transfer head 40 moves up and down and left and right with the transfer member 20 adsorbed to position the transfer member 20 on the folding member 60. The transfer head 40 moves up and down and left and right to position the transfer unit 20-2 of the transfer member 20 overlapping the first groove 61-h of the folding member 60.

Move the transfer head 40 downward so that the transfer unit 20-1 of the transfer member 20 is seated in the first groove 61-h. As can be seen with reference to FIGS. 15 and 16, the second clamp 62, when secured to the clamp fixture 63, has an inwardly inclined shape. The second clamp 62 is formed in such a way that the folding unit 20-2 narrows downwardly so that the folding unit 20-2 folds when the transfer member 20 is seated in the first groove 61-h. Thus, the second clamp 62 may serve to guide the transfer unit 20-1 of the transfer member 20 to be seated in the first groove 61-h.

Therefore, when the transfer unit 20-2 of the transfer member 20 is seated in the first groove 61-h, the folding unit 20-2 is folded axially around the incision groove 20h by the second clamp 62. This causes the transfer member 20 to wrap around at least three sides of the head chuck 43.

The first clamp 42 is moved toward the second clamp 62 to compress the outer side of the second clamp 62. As a result, the second clamp 62 may be firmly secured to the head chuck 43 with the transfer member 20 interposed therebetween.

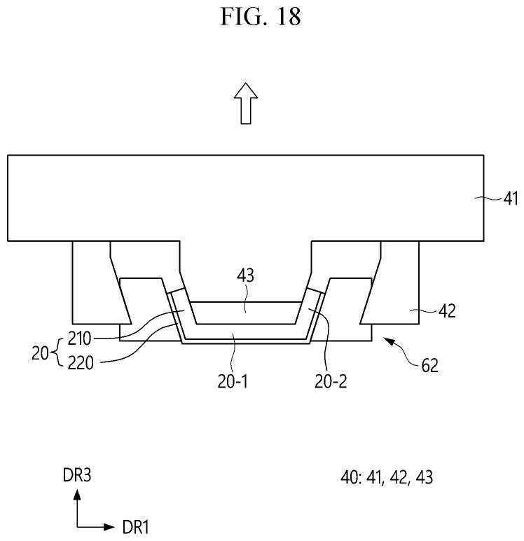

As shown in FIG. 18, the protective film 30 of the transfer unit 20-1 of the transfer member 20 is peeled off (Operation S150 of FIG. 6).

Then, the clamp fixture 63 detaches the second clamp 62, and the transfer head 40 moves upwardly along with the second clamp 62.

Because the adsorption force between the head chuck 43 of the transfer head 40 and the transfer member 20 is better than the adhesion or adhesion force between the transfer member 20 and the protective film 30, the protective film 30 may be easily removed.

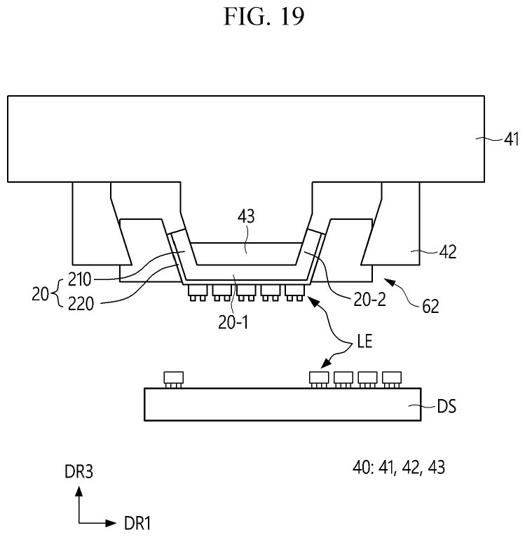

Referring to FIG. 19, the transfer head 40 picks up the light-emitting element LE from a donor substrate DS using the picked-up transfer member 20. (Operation S160 of FIG. 6)

First, the donor substrate DS on which the plurality of light-emitting elements LE are aligned is prepared. The donor substrate DS may have an adhesive material applied to it. The donor substrate DS and the plurality of light-emitting elements LE may be adhered to each other by the adhesive material.

The light-emitting elements LE may include the base substrate SPUB, the n-type semiconductor NSEM, the active layer MQW, the p-type semiconductor PSEM, the first contact electrode CTE1, and the second contact electrode CTE2, as described in FIG. 4. The light-emitting element LE may further include the bonding electrode 23. The junction of the bonding electrode 23 will be described in detail in FIG. 25.

Next, the transfer head 40 transfers the transfer member 20 picked up to the donor substrate DS to bond the light-emitting element LE to one side of the transfer member 20. The light-emitting element LE is bonded to the stamp layer 220 of the transfer unit 20-1 of the transfer member 20.

Then, the transfer head 40 is raised in a third direction (Z direction) to separate the light-emitting element LE from the donor substrate DS.

The transfer head 40 should be pulled in the third direction (Z direction) with a tensile force greater than the adhesion force (or adhesion) between the donor substrate DS and the light-emitting element LE. At this time, the adsorption force between the transfer head 40 and the transfer member 20 must be greater than the adhesion force between the donor substrate DS and the light-emitting element LE in order for the transfer head 40 to desorb the light-emitting element LE from the donor substrate DS through the transfer member 20. According to one or more embodiments, the transfer head 40 utilizes the first clamp 42 to secure the head chuck 43 and the transfer member 20 together. Therefore, even if the transfer head 40 applies the tensile force greater than the adhesion force (or adhesion) between the donor substrate DS and the light-emitting element LE in the third direction (Z direction), the head chuck 43 and the transfer member 20 may be strongly fixed.

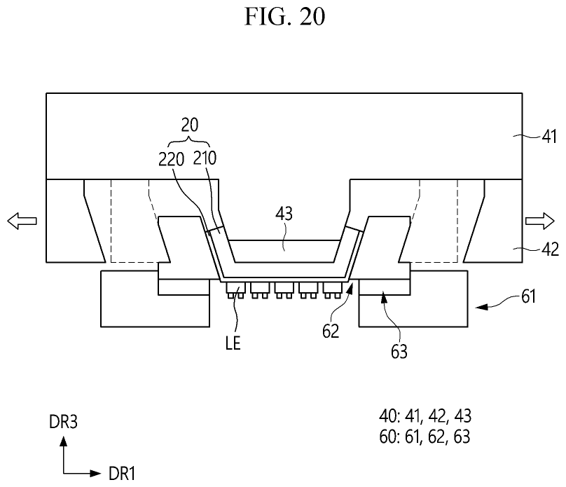

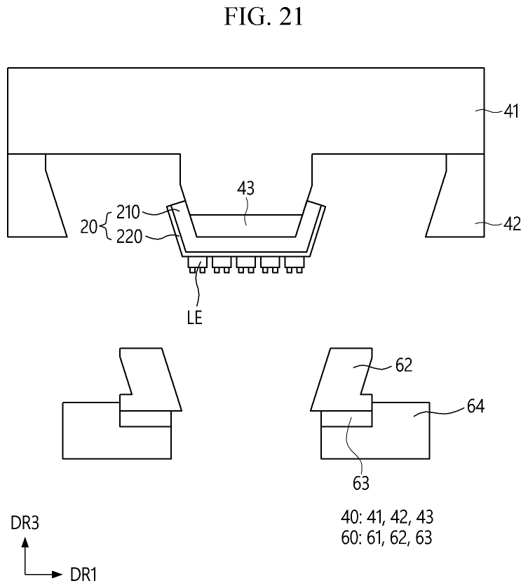

As shown in FIGS. 20 and 21, the transfer head 40 is moved onto the folding member 60, and the folding member 60 removes the second clamp 62 that presses the folding unit 20-2 (Operation S170 of FIG. 6).

The second clamp 62 is located on the clamp fixture 63, and the clamp fixture 63 attaches the second clamp 62. Then, the first clamp 42 is moved to the edge side of the body unit 41. Next, the transfer head 40 is lifted in the third direction (Z direction). Thereby, the second clamp 62 is separated from the transfer head 40.

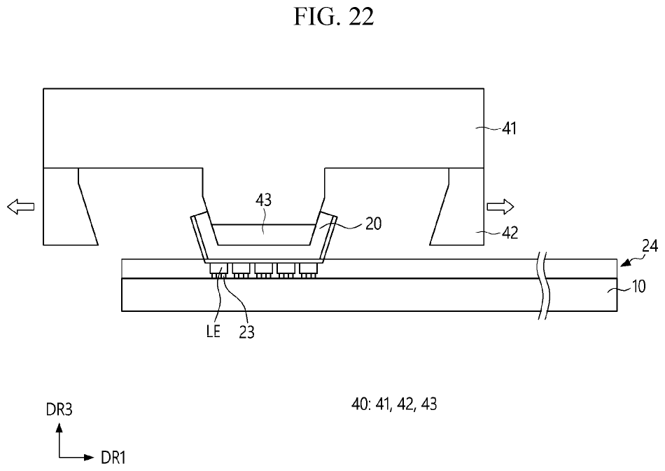

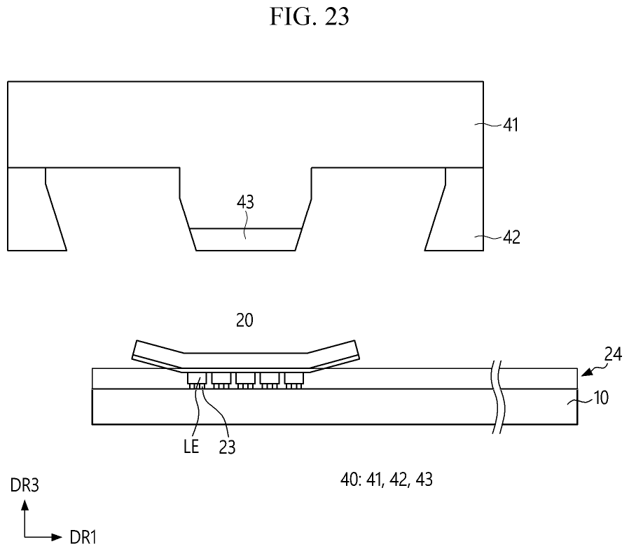

Then, referring to FIGS. 22 and 23, the transfer head 40 aligns the transfer member 20 to which the light-emitting element LE is attached on a circuit board 10, and removes the transfer member 20 from the transfer head 40 (Operation S180 of FIG. 6).

The transfer head 40 transports the transfer member 20 with the light-emitting element LE attached to it to a desired position on the circuit board 10, and then detaches the transfer member 20 from the transfer head 40 by releasing the adsorption of the head chuck 43.

Here, the circuit board 10 may be a substrate SUB including the thin-film transistor layer TFTL of FIG. 4.

The circuit board 10 may be coated with a flux 24 of a desired thickness (e.g., a predetermined thickness). The flux 24 may be a material that facilitates bonding of the circuit board 10 and the bonding electrode 23 in a pressurized melting process using a laser. The flux 24 may be fat-soluble or water-soluble and may include natural or synthetic rosin. The flux 24 may be in liquid form or gel form. The flux 24 is removed after the pressurized melting process is completed.

The flux 24 may be applied at a lower thickness than the light-emitting element LE, but the thickness of the flux 24 may be equal to or thicker than the height of the light-emitting element LE in some areas due to the placement of the light-emitting element LE or the like.

Referring to FIGS. 24-27, after bonding the light-emitting element LE attached to the transfer member 20 to the circuit board 10, the transfer member 20 can be removed. (Operation S190 in FIG. 6)

The light-emitting element LE to be bonded is located on the circuit board 10, and a bonding electrode 23 is located on a first side of the light-emitting element LE abutting the circuit board 10. The transfer member 20 is located on the other side of the light-emitting element LE, so that the circuit board 10, the light-emitting element LE, and the transfer member 20 overlap each other. A laser transmitting member (e.g., a laser transmitter) 8 may be located on the transfer member 20.

The laser transmitting member 8 may be implemented as a material that transmits laser. The laser transmitting member 8 may be realized from any beam-transmissive material.

For example, the laser transmitting member 8 may be realized from one or more of quartz, sapphire, fused silica glass, and/or diamond. However, the physical properties of the laser transmitting member 8 implemented in a quartz material are different from the physical properties of the laser transmitting member 8 implemented in sapphire. For example, when irradiated with a 980 nm laser, the transmittance of the laser transmitting member 8 embodied in the quartz material may be about 85% to about 99%, and the transmittance of the laser transmitting member 8 embodied in the sapphire may be about 80% to about 90%. To reduce or prevent damage to the laser transmitting member 8 realized with the quartz material and to improve durability, a thin film coating layer may be formed on the bottom surface of the laser transmitting member 8 realized with the quartz material. The thin film coating layer formed on the bottom surface of the laser transmitting member 8 may be implemented as a dielectric coating, a conventional optical coating, a SiC coating, or a metallic material coating.

An upper pressurizing member (e.g., an upper pressurizer) 5 may be connected to the laser transmitting member 8. The upper pressurizing member 5 may be pressurized in a first direction. For example, the upper pressurizing member 5 may be pressurized in a first direction in the third direction (Z). Accordingly, the laser transmitting member 8 associated with the upper pressurizing member 5 may press the transfer member 20 in a first direction of the third direction (Z).

The laser may be irradiated to the bonding electrode 23 by penetrating the laser transmitting member 8 and the transfer member 20 by irradiating the bonding electrode 23 with a laser while pressing the transfer member 20 with the laser transmitting member 8. Accordingly, the laser may apply heat to the bonding electrode 23 up to a melting temperature of the bonding electrode 23, thereby pressurized melting bonding the circuit board 10 and the bonding electrode 23. Here, pressurized melting bonding refers to a state in which the bonding electrode 23 is heated and melted by irradiation of the laser so that the light-emitting element LE, the anode pad electrode APD, and the cathode pad electrode CPD are melt mixed, and cooled and solidified when the laser supply is terminated. While being cooled and solidified from the melt-mixed state, the conductivity of the light-emitting element LE and the anode pad electrode APD and cathode pad electrode CPD is maintained, so that the anode pad electrode APD and cathode pad electrode CPD and the light-emitting element LE may be electrically connected and physically connected respectively.

The operation of the upper pressurizing member 5 and the laser transmitting member 8 may be controlled through a control portion (e.g., a controller). For example, the control unit may control the operation of the laser transmitting member 8 using data input from the pressure detection sensor and the height sensor. The control unit may receive data from the pressure sensing sensor to control the upper pressurizing member 5 so that the pressure reaches a target value and may receive data from the height sensor to control the upper pressurizing member 5 and the laser transmitting member 8 so that the height reaches the target value.

In one or more embodiments, the eutectic bonding, in which laser is radiated to the bonding electrode 23 located on one end of the light-emitting element LE to be melt-bonded to the circuit board 10 has been described, but it is not limited thereto. Soldering bonding, in which a solder ball is melted and bonded between the light-emitting element LE and the circuit board 10, anisotropic conductive film bonding (ACF), in which an anisotropic conductive film is heated and bonded between the light-emitting element LE and the circuit board 10, and any of the bonding methods known in the art may be adopted.

The transfer head 40 may then remove the transfer member 20 from the circuit board 10.

The transfer member 20 located on the circuit board 10 to which the light-emitting element LE is bonded is bonded to the transfer head 40, and a force greater than the adhesion force between the light-emitting element LE and the transfer member 20 pulls the transfer member 20 from the transfer head 40 in the third direction (Z direction). Thereby, the transfer member 20 is detached from the circuit board 10 to which the light-emitting element LE is bonded. At this time, the adhesion force between the light-emitting element LE and the circuit board 10 may be the highest, the adhesion force between the transfer member 20 and the transfer head 40 may be the next highest, and the adhesion force between the light-emitting element LE and the transfer member 20 may be the lowest. Therefore, when the circuit board 10, the light-emitting element LE, the transfer member 20, and the transfer head 40 are superimposed in the third direction (Z direction) and a force is applied in the third direction (Z direction), the light-emitting element LE and the transfer member 20 with the lowest adhesion force may be detached from each other.

Next, referring to FIG. 26, the flux 24 on the circuit board 10 to which the light-emitting element LE is bonded is removed using a flux cleaner. As the flux cleaner, a known flux cleaner (for example, a water-based flux cleaner) may be used. For example, flux cleaners such as CLEANTHROUGH 750HS and CLEANTHROUGH 750K from Kao Corporation, PINE ALPHA ST-100S from Arakawa Chemical Industries, Ltd. may be used, but are not limited to.

The cleaning conditions for cleaning the circuit board 10 are not particularly limited. For example, the circuit board 10 may be cleaned at a cleaning agent temperature of about 30° C. to about 50° C. for about 1 minute to about 5 minutes (for example about 40° C. for about 2 minutes to about 4 minutes).

The light-emitting element LE may contact the anode pad electrode APD and the cathode pad electrode CPD of the circuit board 10 through the bonding electrode 23. As described with reference to FIG. 4, the first contact electrode CTE1 of the light-emitting element LE may be in contact with the anode pad electrode APD of the circuit board 10, and the second contact electrode CTE2 of the light-emitting element LE may be in contact with the cathode pad electrode CPD.

In one or more embodiments, a flip-chip light-emitting element is illustrated, but it is not limited thereto, and a vertical-type light-emitting element may also be used.

As described in one or more embodiments, by removing the protective film 30 attached to the folding unit 20-2 of the transfer member 20 by the inversion member 90 and then performing folding, a phenomenon of peeling or pushing of the protective film 30 during folding may be reduced or prevented.

In addition, because the transfer member is removed after the bonding process, it is possible to reduce or prevent flux applied to the circuit board from directly contacting the laser transmitting member, thereby reducing or preventing contamination of the laser transmitting member.

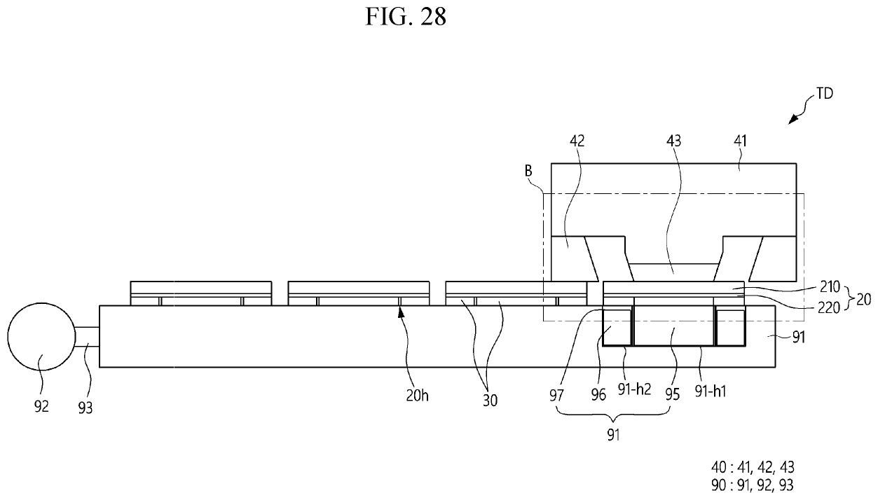

FIG. 28 is a diagram illustrating a configuration of the transfer device of a light-emitting element according to one or more other embodiments.

Referring to FIG. 28, the transfer device TD of the light-emitting element according to one or more embodiments may include the transfer member 20, the protective film 30, the inversion member 90, and the transfer head 40.

The transfer device TD of the light-emitting element of FIG. 28 differs from the transfer device TD of the light-emitting element of FIG. 5 in that the inversion member 90 includes a vertical movement unit (e.g., a vertical mover) 96 that serves as the folding member 60 of FIG. 5. Therefore, the description of the same components will be omitted, and the description will focus on the differences.

Referring to FIG. 28, the inversion member 90 may include a stage 91, a rotation shaft 92, and a connection 93 connecting the stage 91 and the rotation shaft 92. The stage 91 may be rotated about 180 degrees about the rotation shaft 92.

In addition, the stage 91 may include the support chuck 95, the vertical movement unit 96, and the side chuck 97. The stage 91 supports the transfer member 20, and the stage 91 may have the plurality of grooves 91-h1, 91-h2, with the support chuck 95 and the vertical movement unit 96 embedded and located within the plurality of grooves 91-h1, 91-h2.

The support chuck 95 may be located in the first groove 91-h1 formed in the central portion of the stage 91, and the vertical movement unit 96 may be located in the second groove 91-h2 located adjacent to the first groove 91-h1. The side chuck 97 may be located on the vertical movement unit 96.

The support chuck 95 and the side chuck 97 may be any one of the electrostatic chuck, the adhesive chuck, the vacuum chuck, and/or the porous vacuum chuck. The stage 91 may utilize the plurality of chucks to adsorb one side of the protective film 30.

When the inversion member 90 picks up one or more transfer members 20 and reverses them up, down, left, and right, the transfer member 20 may be adsorbed through the support chuck 95 and the side chuck 97. The vertical movement unit 96 is movable up and down in the second groove 91-h2.

For example, the vertical movement unit 96 may further include a vertical drive unit (e.g., a vertical actuator) for moving the vertical movement unit 96 up and down. The vertical drive unit may be provided in a first region of the stage 91 and may include a hydraulic cylinder and a linkage. The hydraulic cylinder may provide a driving force for the vertical movement unit 96. A hydraulic pump may be connected to the hydraulic cylinder. The hydraulic pump may further include a hydraulic handle for regulating the hydraulic pump. The hydraulic cylinder may further include additional members for redirecting the driving force based on the position of the hydraulic cylinder and the hydraulic pump. The configuration for vertically moving the vertical movement unit 96 is only an example, and is not limited thereto, and other conventionally known methods may be employed.

Each of these components will be described in more detail with reference to the following drawings, together with a description of a transfer method utilizing them.

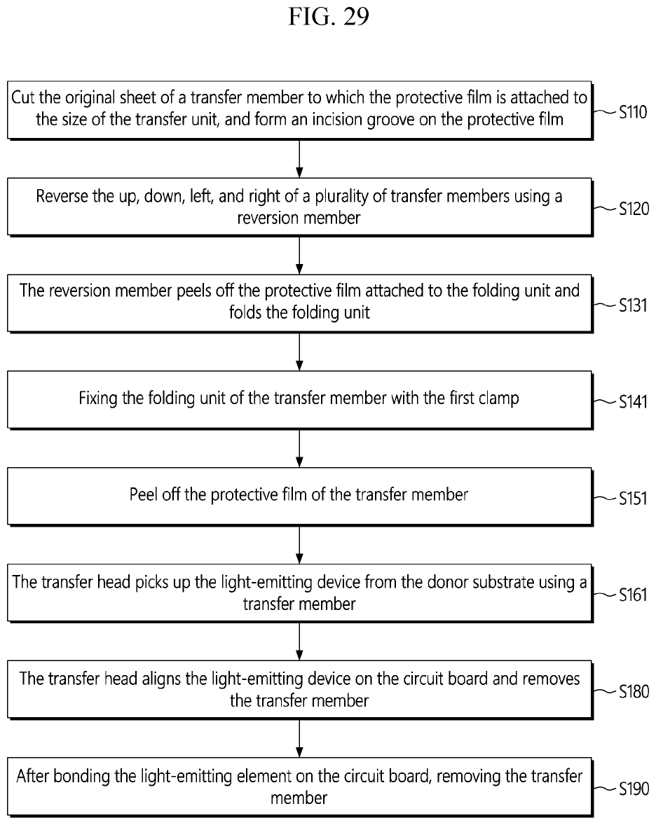

Hereinafter, FIG. 29 is a flow diagram illustrating a method of transcribing a light-emitting element performed using the light-emitting element transcription device of FIG. 28.

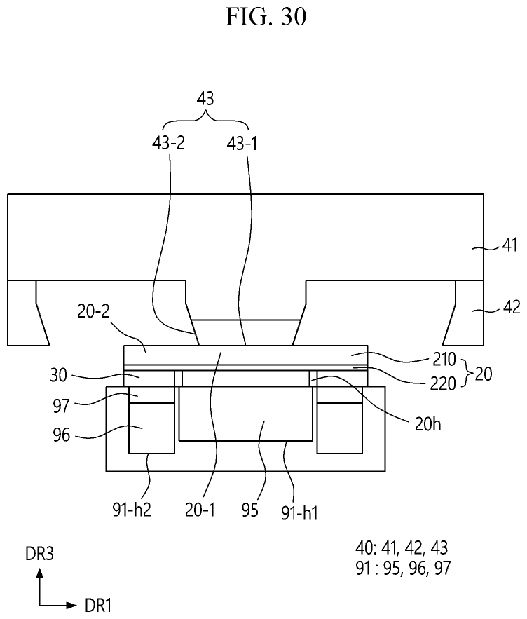

FIGS. 30-34 are drawings to illustrate the operation of the light-emitting element transfer device of FIG. 28. FIG. 30 is an enlarged view of an area B of FIG. 28.

First, the ledger of the transfer member with the protective film attached is cut to the size of the transfer unit, and the incision groove 20h is formed on the protective film. (Operation S110 in FIG. 29)

Next, the one or more transfer members 20 are picked up and inverted up, down, left, and right using the inversion member 90. (Operation S120 of FIG. 29)

Thereby, the transfer members 20 may be arranged with the protective film 30, the stamp layer 220, and the base layer 210 in order due to the inversion member 90.

Because the Operations S110 and S120 of FIG. 29 described above are similar to the Operations S110 to S120 of FIG. 6, a redundant description is omitted.

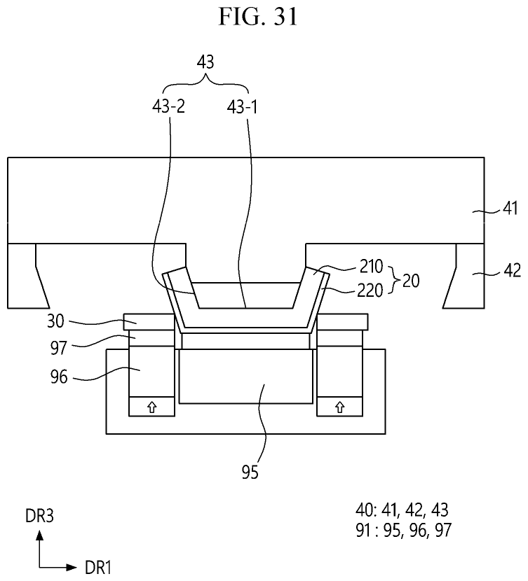

Referring to the following FIGS. 30 and 31, the inversion member (e.g., an inverter) 90 peels off the protective film attached to the folding unit 20-2 and folds up the folding unit 20-2. (Operation S131 of FIG. 29)

When the transfer member 20 is located on the inversion member 90, the transfer unit 20-1 overlaps with the support chuck 95 and does not overlap with the vertical movement unit 96. The folding unit 20-2 overlaps the vertical movement unit 96 and does not overlap the support chuck 95. The protective film 30 of the folding unit 20-2 may be adsorbed by the side chucks 97.

The side chucks 97 located on the vertical movement unit 96 may move up and down together according to the up-and-down movement of the vertical movement unit 96.

The folding unit 20-2 of the transfer member 20 is located superimposed on the vertical movement unit 96, so that when the vertical movement unit 96 rises in the third direction (Z direction), the folding unit 20-2 receives a force in the upward direction.

Even when the vertical movement unit 96 rises and the folding unit 20-2 is subjected to a force in the upward direction, the side chucks 97 maintain an adsorption state, so that the protective film 30 attached to the folding unit 20-2 remains adsorbed to the side chucks 97. The adsorption force between the protective film 30 and the side chucks 97 is better than the adhesion force between the protective film 30 and the stamp layer 220.

On the other hand, the transfer unit 20-1 is subjected to a fixing force by the adsorption force of the support chuck 95. Therefore, when the vertical movement unit 96 rises in the third direction (Z direction), the folding unit 20-2 of the transfer member 20 is folded up axially in the incision groove 20h, and the base layer 210 of the folding unit 20-2 contacts the inclined unit 43-2 of the head chuck 43. This allows the transfer member 20 to wrap around at least three sides of the head chuck 43. On the other hand, the protective film 30 of the folding unit 20-2 remains adsorbed with the side chuck 97, and the adsorption force between the protective film 30 and the side chuck 97 is better than the adhesion force between the protective film 30 and the stamp layer 220. Therefore, when the folding unit 20-2 is folded, the protective film 30 is peeled off from the folding unit 20-2.

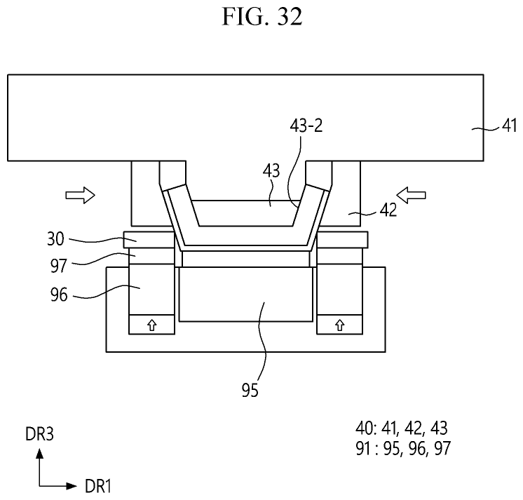

Referring to FIG. 32, the folded folding unit 20-2 of the transfer member 20 is secured with the first clamp 42. (Operation S141 in FIG. 29)

The first clamp 42 is moved to the head chuck 43 side, and the folded folding unit 20-2 is pressed against the inclined unit 43-2 of the head chuck 43.

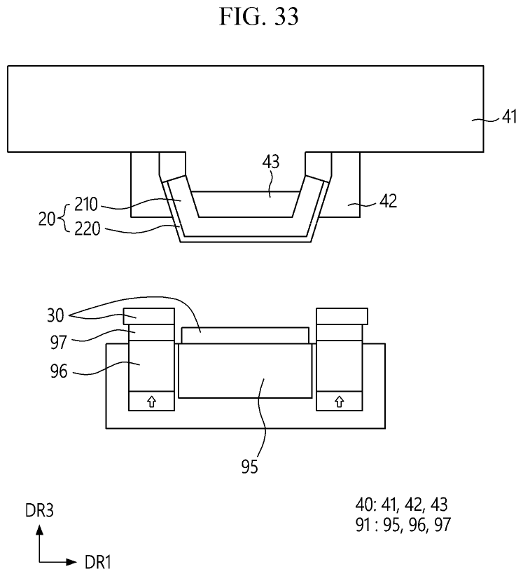

Then, as shown in FIG. 33, the protective film 30 of the transfer unit 20-1 of the transfer member 20 is peeled off. (Operation S151 of FIG. 29)

While the support chuck 95 maintains the adsorption function, the transfer head 40 is moved upwardly together with the second clamp 62. Thereby, the protective film 30 of the transfer unit 20-1 is peeled off from the stamp layer 220 of the transfer member 20.

The adsorption force by which the support chuck 95 adsorbs the protective film 30 is better than the adhesion or adhesion force between the transfer member 20 and the protective film 30. Also, the adsorption force between the head chuck 43 of the transfer head 40 and the transfer member 20 is better than the adhesion or adhesion force between the transfer member 20 and the protective film 30. Therefore, the protective film 30 may be easily removed from the transfer member 20.

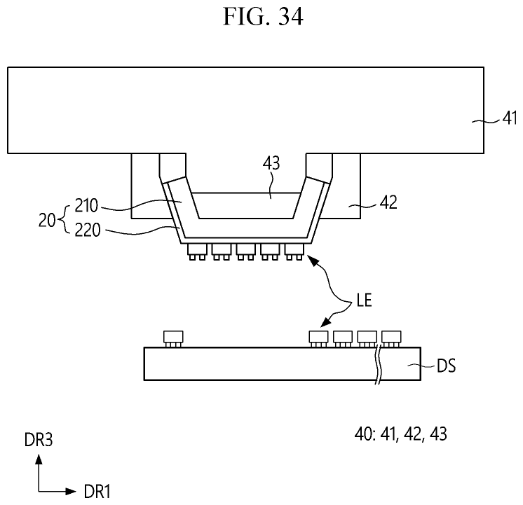

Referring to FIG. 34, the transfer head 40 picks up the light-emitting element LE from the donor substrate DS using the picked-up transfer member 20. (Operation S161 of FIG. 29)

First, prepare the donor substrate DS on which the plurality of light-emitting elements LE are aligned. The donor substrate DS may have the adhesive material applied to it. The donor substrate DS and the plurality of light-emitting elements LE may be adhered to each other by the adhesive material.

Next, the transfer head 40 transfers the transfer member 20 picked-up to the donor substrate DS to bond the light-emitting elements LE on one side of the transfer member 20. The light-emitting element LE is bonded to the stamp layer 220 of the transfer unit 20-1 of the transfer member 20.

Then, the transfer head 40 is raised in the third direction (Z direction) to separate the light-emitting element LE from the donor substrate DS.

The transfer head 40 should be pulled in the third direction (Z direction) with the tensile force greater than the adhesion (or adhesion) between the donor substrate DS and the light-emitting element LE. At this time, the adsorption force between the transfer head 40 and the transfer member 20 must be greater than the adhesion force between the donor substrate DS and the light-emitting element LE in order for the transfer head 40 to desorb the light-emitting element LE from the donor substrate DS through the transfer member 20. According to one or more embodiments, the transfer head 40 utilizes the first clamp 42 to secure the head chuck 43 and the transfer member 20 together. Therefore, even if the transfer head 40 applies the tensile force greater than the adhesion force (or adhesion) between the donor substrate DS and the light-emitting element LE in the third direction (Z direction), the head chuck 43 and the transfer member 20 may be strongly fixed.

Then, referring to FIGS. 22 and 23, the transfer head 40 aligns the transfer member 20 with the light-emitting element LE attached to it on the circuit board 10, and the transfer member 20 is removed from the transfer head 40. (Operation S180 of FIG. 29)

Referring to FIGS. 24-27, the transfer member 20 may be removed after bonding the light-emitting element LE attached to the transfer member 20 to the circuit board 10. (Operation S190 of FIG. 29)

Because the Operations S180 and S190 of FIG. 29 described above are similar to the Operations S180 to S190 of FIG. 6, the redundant description will be omitted.

In the aforementioned one or more embodiments, a method of reversing the stacking order of the base layer 210, the stamp layer 220, and the protective film 30 stacked sequentially on the support member Sta is described by the inversion member 90.

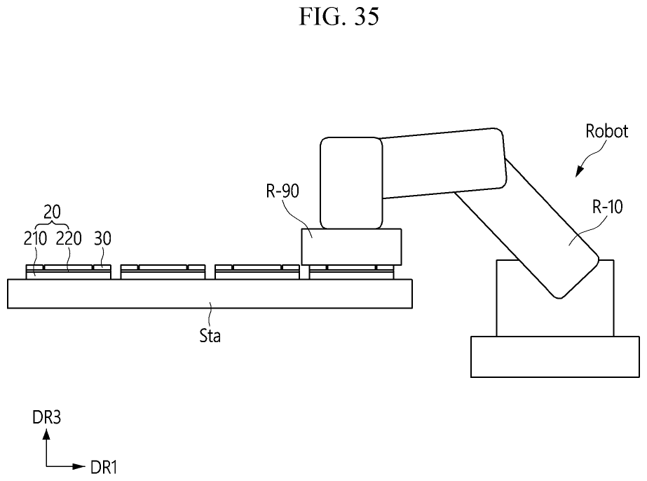

FIGS. 35-40 are drawings to illustrate a configuration of the transfer device of the light-emitting element according to one or more embodiments.

Referring to FIGS. 35-40, an articulated robot Robot having a plurality of joints replaces the inversion member 90 and reverses the stacking order of the base layer 210, the stamp layer 220, and the protective film 30 stacked sequentially on the support member Sta.

More specifically, the articulated robot may include a body R-10 having multiple joints and a suction unit (e.g., an adsorption device) R-90 configured at a leading edge of the body R-10 for lifting the transfer member 20 received on the support member Sta. The suction unit R-90 includes a first chuck R-95 for joining the transfer member 20, and a second chuck R-97 for suctioning the folding unit 20-2. The body R-10 of the articulated robot may apply the technology of the present disclosure, and a detailed description is omitted. Using the first chuck R-95 for bonding, the articulated robot may rotate a first side of the protective film 30 by about 180 degrees while adsorbing the protective film 30, so that the transfer member 20 to which the protective film 30 is attached may be inverted up and down and left and right. Thus, the transfer member 20 to which the protective film 30 is attached may be positioned with the protective film 30 at the bottom and the transfer member 20, i.e., the stamp layer 220 and the base layer 210, on the protective film 30 in order.

The articulated robot may fold the transfer member 20 and peel the protective film 30 from the transfer member 20 using the first chuck R-95, the second chuck R-97, and the vertical movement unit (e.g., a vertical mover) R-96.

The first chuck R-95, which includes a first chuck R-97, a second chuck R-97, and the vertical movement unit R-96 for bonding, is similar to the inversion member 90 described with reference to FIGS. 30-33, so a detailed description will be omitted.

An articulated robot may transport the folded transfer member 20 to a location on the donor substrate DS. In one or more embodiments, the support member Sta may be moved by the articulated robot Robot to adsorb the transfer member 20 with the protective film 30 attached. Thereafter, the same process as in FIGS. 14-21 may be performed.

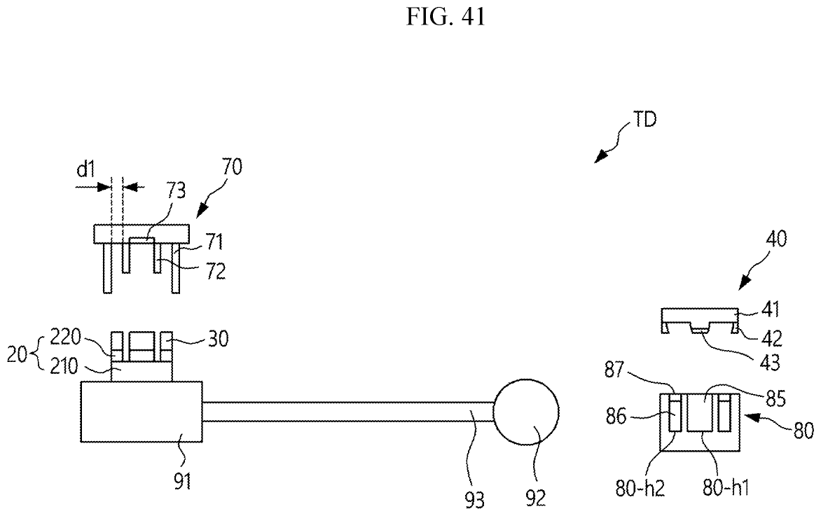

Hereinafter, an apparatus and method for transferring the light-emitting element according to one or more embodiments will be described with reference to FIGS. 41-50.

FIG. 41 is a drawing illustrating a configuration of a light-emitting element transfer device according to one or more embodiments.

Referring to FIG. 41, a transfer device TD of a light emitting-element according to one or more embodiments may include the transfer member 20, the protective film 30, a cutting member (e.g., a cutter) 70, an inversion member 90, a loading member (e.g., a loader) 80, and a transfer head 40.

The transfer device TD of the light emitting-element of FIG. 41 differs from the transfer device TD of the light-emitting element of FIG. 5 in that it further includes the cutting member 70 and the loading member 80. Therefore, a description of the same components will be omitted, and the description will focus on the differences.

The cutting member 70 is a mold for cutting a ledger of the transfer member to a transfer unit size and concurrently (e.g., simultaneously) forming the incision groove 20h and may include a first cutter 71 for cutting the transfer unit size, a second cutter 72 for forming the incision groove 20h, and a third chuck 73. The first cutter 71 passes through the transfer member 20 to which the protective film 30 is attached. The second cutter 72, on the other hand, is formed shorter than the first cutter 71 so that it only incises a portion of the protective film 30 or transfer member 20. The length of the folding unit 20-2 may be determined by the distance D1 between the second cutter 72 and the first cutter 71. The third chuck 73 may lift the transfer member 20, which has been cut into transfer units, and move it to a desired position.

The loading member 80 may include a support chuck 85, a vertical movement unit (e.g., a vertical mover) 86, and a side chuck 87. The loading member 80 may include a plurality of grooves 80-h1, 80-h2, with the support chuck 85 and the vertical movement unit 86 embedded and located within the plurality of grooves.

The support chuck 85 may be located in a first groove 80-h1 formed in a central portion of the loading member 80, and the up-vertical movement unit 86 may be located in a second groove 80-h2 located adjacent to the first groove 80-h1. The side chuck 87 may be located on the vertical movement unit 86.

The support chuck 85 and the side chuck 87 may be any one of the electrostatic chuck, the adhesive chuck, the vacuum chuck, and/or the porous vacuum chuck. The loading member 80 may utilize a plurality of chucks to adsorb a first side of the protective film 30.

In one or more embodiments, it may further include the vertical drive unit for moving the vertical movement unit 86 up and down. The vertical drive unit may be provided in a first region of the loading member 80 and may include the hydraulic cylinder and the linkage. The hydraulic cylinder may provide the driving force for the vertical movement unit 86. A hydraulic pump may be connected to the hydraulic cylinder. The hydraulic pump may further include a hydraulic handle for regulating the hydraulic pump. The hydraulic cylinder may further include additional members for redirecting the driving force based on the position of the hydraulic cylinder and the hydraulic pump. The configuration for moving the vertical movement unit 86 up and down is an example only and is not limited thereto, and other methods known in the art may be employed.

Each component will be described in more detail with reference to the following drawings, together with a description of a transfer method utilizing them.

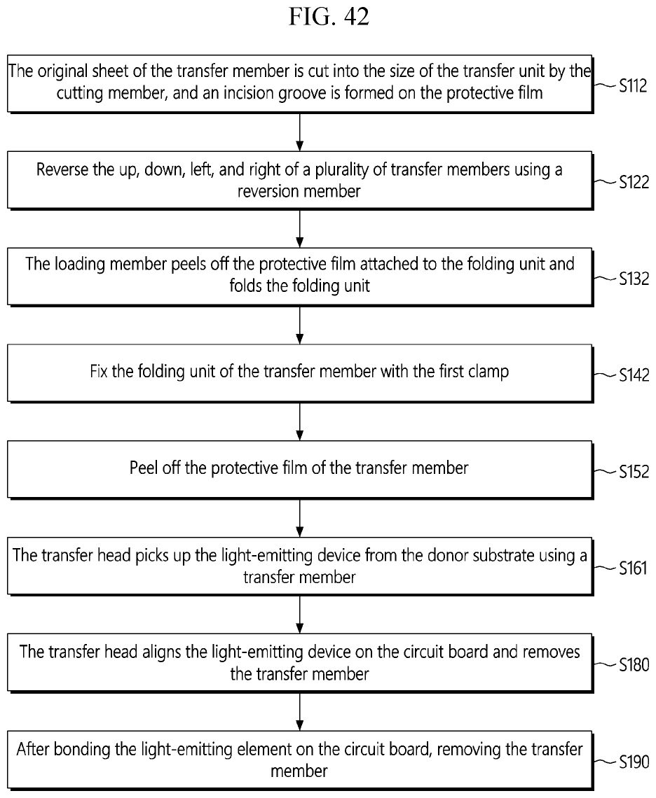

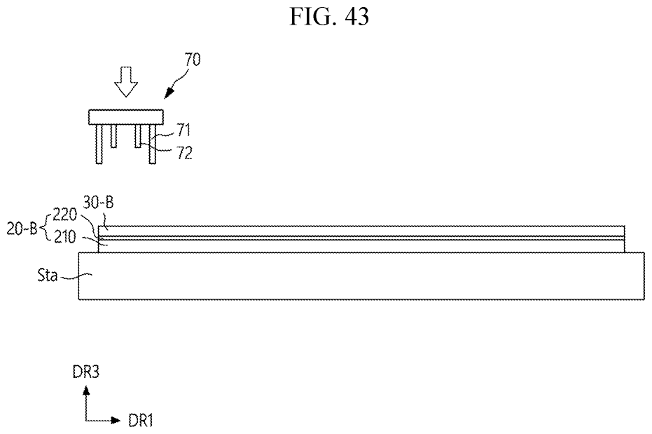

FIG. 42 is a flow diagram to illustrate the operation of the light-emitting element of FIG. 41. FIGS. 43-50 are drawings to illustrate the operation of the transcription device of the light-emitting element.

First, referring to FIG. 43, the ledger of the transfer member to which the protective film is attached is cut to the size of the transfer unit, and the incision groove 20h is formed on the protective film. (Operation S112 of FIG. 42)

The ledger 20-B of the transfer member to which the ledger 30-B of the protective film is attached is arranged by sequentially stacking the base layer 210, the stamp layer 220, and the protective film 30-B from the support member Sta. The base layer 210 is in contact with the support member Sta on one side and the stamp layer 220 on the other side, and the stamp layer 220 is in contact with the base layer 210 on one side and the protective film 30-B on the other side.

The ledger 20-B of the transfer member to which the ledger 30-B of the protective film located on the support member Sta is attached is cut to the size of the transfer unit by the cutting member 70, while forming the incision groove 20h on the protective film 30. The incision groove 20h is formed in the protective film 30 in the direction of the base layer 210, and the incision groove 20h has a depth at least equal to or greater than the thickness of the protective film 30. The incision groove 20h is formed to at least penetrate the protective film 30 and may be formed in a portion of the transfer member 20 but the incision groove 20h is not formed to penetrate the entire transfer member 20.

Then, the one or more transfer members 20 are picked up and inverted upside down and downside up using the inversion member 90. (Operation S122 in FIG. 42)

The cutting member 70 places the transfer member 20, which is cut in transfer units, on a first side of the inversion member 90 using the third chuck 73. The transfer member 20 may have the base layer 210, the stamp layer 220, and the protective film 30 arranged in order from the inversion member 90.

While the inversion member 90 adsorbs one side of the transfer member 20, the transfer member 20 with the protective film 30 attached may be rotated about 180 degrees to reverse the transfer member 20 up and down and left and right. The transfer member 20 is then placed on the first side of the loading member 80.

Thereby, the transfer member 20 may be located of the protective film 30, the stamp layer 220, and the base layer 210 in order from the loading member 80. The transfer unit 20-1 may be located on the support chuck 85 of the loading member 80, and the folding unit 20-2 may be located on the side chuck 87.

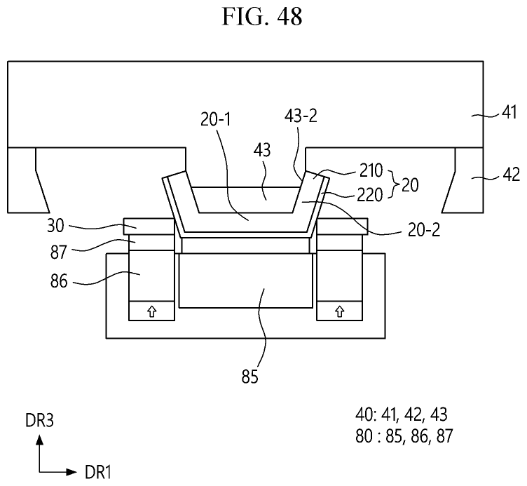

Next, as shown in FIGS. 47 and 48, the loading member 80 peels off the protective film 30 attached to the folding unit 20-2 and folds the folding unit 20-2. (Operation S132 in FIG. 42)

When the transfer member 20 is located on the loading member 80, the transfer unit 20-1 overlaps the support chuck 85 and does not overlap the vertical movement unit 86. The folding unit 20-2 overlaps the vertical movement unit 86 and does not overlap the support chuck 85. The protective film 30 of the folding unit 20-2 may be adsorbed by the side chucks 87.

The side chucks 87 located on the vertical movement unit 86 may move up and down together according to the up-and-down movement of the vertical movement unit 86.

Because the folding unit 20-2 of the transfer member 20 is located superimposed on the vertical movement unit 86, the folding unit 20-2 receives a force in the upward direction when the vertical movement unit 86 rise in the third direction (Z direction).

Even when the folding unit 20-2 is subjected to a force in the upward direction due to the upward movement of the vertical movement unit 86, the side chuck 87 remains in an adsorbed state. Therefore, the protective film attached to the folding unit 20-2 remains adsorbed to the side chuck 87. The adsorption force between the protective film 30 and the side chuck 87 is better than the adhesion force between the protective film 30 and the stamp layer 220.

On the other hand, the transfer unit 20-1 is subjected to the fixing force by the adsorption force of the support chuck 85. Therefore, when the vertical movement unit 86 rises in the third direction (Z direction), the folding unit 20-2 of the transfer member 20 is folded up axially in the incision groove 20h, and the base layer 210 of the folding unit 20-2 contacts the inclined unit 43-2 of the head chuck 43. This allows the transfer member 20 to wrap around at least three sides of the head chuck 43. On the other hand, the protective film 30 of the folding unit 20-2 remains adsorbed with the side chuck 87, and the adsorption force between the protective film 30 and the side chuck 87 is better than the adhesion force between the protective film 30 and the stamp layer 220. Therefore, when the folding unit 20-2 is folded, the protective film 30 is peeled off from the folding unit 20-2.

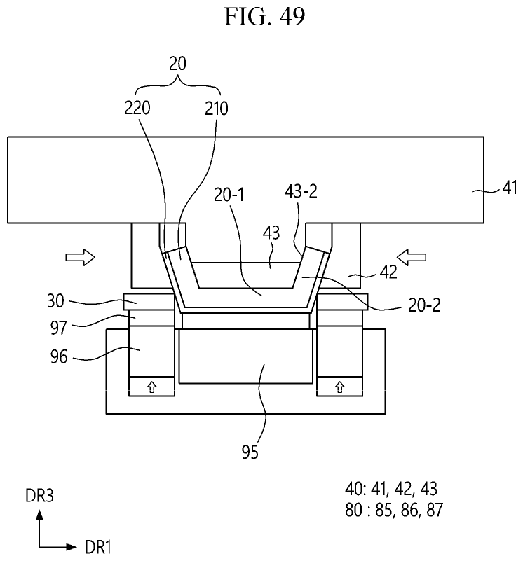

Next, referring to FIG. 49, the folded folding unit 20-2 of the transfer member 20 is fixed with the first clamp 42. (Operation S142 in FIG. 42)

The first clamp 42 is moved toward the head chuck 43 to press the folded folding unit 20-2 against the inclined unit 43-2 of the head chuck 43.

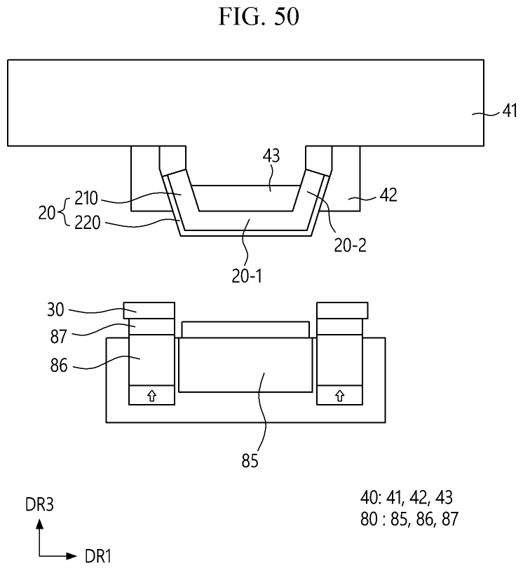

Then, as shown in FIG. 50, the protective film 30 of the transfer unit 20-1 of the transfer member 20 is peeled off. (Operation S152 of FIG. 42)

Operation S152 of FIG. 42 is similar to the description of Operation S151 of FIG. 29 described with reference to FIG. 33, so a detailed description will be omitted.

Referring to FIG. 34, the transfer head 40 picks up the light-emitting element LE from the donor substrate DS using the picked-up transfer member 20. (Operation S161 of FIG. 42)

Then, referring to FIGS. 22 and 23, the transfer head 40 aligns the transfer member 20 with the light-emitting element LE attached to it on the circuit board 10, and removes the transfer member 20 from the transfer head 40. (Operation S180 of FIG. 42)

Referring to FIGS. 24-27, after bonding the light-emitting element LE attached to the transfer member 20 to the circuit board 10, the transfer member 20 may be removed. (Operation S190 of FIG. 42)

The Operations S161, S180, and S190 of FIG. 42 described above are similar to the Operations S161, S180 to S190 of FIG. 29, so the redundant description is omitted.

As described in the foregoing embodiments, the problem of a poor transfer process in which contaminants remain on top of the base layer may be solved by cutting the protective film in a reverse position with the protective film facing upward.

Furthermore, it is possible to reduce or prevent the likelihood of the head chuck being contaminated by flux or the like by folding the transfer member to the head chuck side of the transfer head.

It is possible to reduce or prevent the likelihood of the protective film being peeled off or pushed off during folding after removing the protective film attached to the folding unit of the transfer member by folding the transfer member.

It is possible to reduce or prevent the likelihood of dislodgement between the transfer member and the chuck when picking up the light-emitting element by using the clamp to secure the transfer member. Ultimately, this may improve production yields by reducing or minimizing transfer rejects that occur during the transfer process.

However, the aspects of the disclosure are not restricted to the one set forth herein. The above and other aspects of the present disclosure will become more apparent to one of daily skill in the art to which the present disclosure pertains by referencing the claims, with functional equivalents thereof to be included therein.

What is claimed is:

1. A transfer device of a light-emitting element, the transfer device comprising:
a transferer comprising a transferring portion, a folding portion at an edge, a stamp layer having a tacky or adhesive surface, and a base layer above one surface of the stamp layer;
a protective film above an other surface of the stamp layer, and defining an incision groove with the transferring portion at a center thereof on a plane;
an inverter for inverting up, down, left, and right sides of the transferer, and comprising a support chuck configured to adsorb the protective film overlapping the transferring portion, and a side chuck configured to adsorb the protective film overlapping the folding portion;
a transfer head having a head chuck configured to be adsorbed to the base layer, and movable up, down, left, and right; and
a folder comprising a detachable first clamp.

2. The transfer device of claim 1, wherein the folder further comprises:
a clamp support defining a first groove in which the transferring portion of the transferer is able to be seated; and
a clamp fixture around the first groove,
wherein the first clamp is detachably on the clamp fixture, and is configured to fix the folding portion that is folded.

3. The transfer device of claim 2, wherein the first clamp is in divided units that are inclined in a first groove direction, and is in a structure that becomes narrower as it goes downward and that is configured to guide the transferer to the first groove.

4. The transfer device of claim 2, wherein the transfer head comprises:
a body;
the head chuck at a center of the body, and configured to be adsorbed to the transferring portion of the transferer; and
a second clamp movable between an edge of the body and the head chuck.

5. The transfer device of claim 4, wherein the second clamp is configured to fix the first clamp for fixing the folding portion that is folded.

6. A transfer device of a light-emitting element, the transfer device comprising:
a transferer comprising a transferring portion, a folding portion at an edge, a stamp layer having a tacky or adhesive surface, and a base layer above one surface of the stamp layer;
a protective film above the other surface of the stamp layer, and defining an incision groove an a center thereof on a plane;
an inverter above a support chuck capable of adsorbing the protective film overlapping with the transferring portion, and configured to invert up, down, left, and right sides of the transferer;
a transfer head having a head chuck adsorbed to the base layer and movable up, down, left, and right;
a vertical mover adjacent to the support chuck, capable of vertical movement; and
a side chuck for adsorbing the protective film overlapping the folding portion.

7. The transfer device of claim 6, wherein the folding portion is foldable around the incision groove by upward driving of the vertical mover.

8. The transfer device of claim 7, wherein the transfer head comprises:
a body;
the head chuck at a center of the body, and configured to be adsorbed to the transferring portion of the transferer; and
a clamp movable between the edge of the body and the head chuck, and fixable to the folding portion that is folded.

9. The transfer device of claim 6, wherein the inverter is attached to a front end of a body of an articulated robot having joints.

10. A transfer device of a light-emitting element comprising:
a transferer comprising a transferring portion, a folding portion at an edge, a stamp layer having a tacky or adhesive surface, and a base layer above one surface of the stamp layer;
a protective film above the other surface of the stamp layer, and defining an incision groove with the transferring portion at a center thereof on a plane;
an inverter for inverting up, down, left, and right sides of the transferer;
a transfer head having a head chuck adsorbed to the base layer and movable up, down, left, and right; and
a loader having chucks configured to be adsorbed to the protective film of the transferer;
a support chuck below the loader, and configured to adsorb the protective film overlapping with the transferring portion;
a vertical mover adjacent to the support chuck and configured to perform vertical movement; and
a side chuck configured to adsorb the protective film overlapping the folding portion.

11. The transfer device of claim 10, further comprising a cutter for forming a cutting groove of the transferer, and comprising a first cutter for cutting the transferer to an arbitrary size from an original sheet of the transferer to which the protective film is attached, a second cutter for forming the incision groove penetrating the protective film, and a chuck configured to adsorb the transferer.

12. The transfer device of claim 11, wherein the folding portion is foldable around the incision groove by upward driving of the vertical mover.

13. The transfer device of claim 12, wherein the transfer head comprises:
a body;
the head chuck at a center of the body and configured to be adsorbed to the transferring portion of the transferer; and
a clamp movable between the edge of the body and the head chuck, and fixable to the folding portion that is folded.

14. The transfer device of claim 10, wherein the light-emitting element comprises an n-type semiconductor, an active layer, a p-type semiconductor, a first contact electrode, and a second contact electrode.

15. A method of transferring a light-emitting element comprising:
cutting an original sheet of a transferer having a protective film on a support into a size of a transferring portion, and forming an incision groove on the protective film to define a folding portion and the transferring portion;
inverting up, down, left, and right sides of transferers using an inverter;
peeling off the protective film attached to the folding portion by a side chuck of the inverter;
folding the transferer in the folding portion with a first clamp of the folding portion around the incision groove;
fixing the folding portion that is folded in a state where a transfer head is configured to adsorb the transferring portion;
fixing the first clamp by a second clamp of the transfer head;
lifting the transferer that is folded by the first clamp;
peeling off the protective film of the transferring portion;
picking up the light-emitting element from a donor substrate by adsorption;
lifting the light-emitting element to the transferring portion by the transfer head;
unclamping the first clamp and the second clamp;
attaching the first clamp to the folding portion;
aligning the light-emitting element on a circuit board by the transfer head; and
detaching the transferer from the transfer head.

16. The method of claim 15, wherein the folding portion comprises:
a clamp support defining a first groove for seating the transferring portion;
a clamp fixture around the first groove; and
the first clamp detachably on the clamp fixture, and configured to fix the folding portion that is folded,
wherein the transferring portion of the transferer is seated in the first groove, the folding portion of the transferer is folded around the incision groove, the first clamp supports the folding portion, and the second clamp of the transfer head fixes the first clamp.

17. The method of claim 15, further comprising:
bonding the light-emitting element attached to the transferer onto the circuit board; and
removing the transferer by peeling it from the light-emitting element bonded to the circuit board by the transfer head.

18. The method of claim 15, wherein the transferer comprises a base layer, and a stamp layer above one surface of the base layer and comprising a material having tacky or adhesive properties, and
wherein the protective film is above another side of the stamp layer.

19. The method of claim 18, wherein the base layer, the stamp layer, and the protective film are sequentially on the support.

20. A method of transferring a light-emitting element comprising:
cutting an original sheet of a transferer having a protective film on a support into size of a transferring portion;
forming an incision groove on the protective film to define a folding portion and the transferring portion;
picking up the transferer using an inverter;
inverting the transferer up, down, left, and right;
folding up the folding portion by adsorbing the protective film attached to the folding portion by a side chuck of the inverter and raising a vertical mover of the inverter below the folding portion in a state in which a transfer head configured to adsorb the transferring portion;
fixing the folding portion that is folded with a clamp of the transfer head;
lifting the transferer;
peeling off the protective film of the transferer;
picking up the light-emitting element from a donor substrate by adhering the light-emitting element to the transferer by the transfer head;
detaching the clamp from the folding portion by releasing the clamp and fixing the clamp to the folding portion;
arranging the light-emitting element on a circuit board by the transfer head; and
detaching the transferer from the transfer head.

21. The method of claim 20, further comprising:
bonding the light-emitting element attached to the transferer onto the circuit board; and
removing the transferer by peeling it from the light-emitting element bonded to the circuit board by the transfer head.

22. A method of transferring a light-emitting element comprising:
cutting an original sheet of a transferer into a size of a transferring portion by a cutter;
forming an incision groove on a protective film to define a folding portion and the transferring portion;
picking up transferers using an inverter;
inverting the transferers up, down, left, and right;
folding up the folding portion by adsorbing the protective film attached to the folding portion by a side chuck of a loader, and raising a vertical mover of the inverter below the folding portion in a state in which a transfer head adsorbs the transferring portion;
fixing the folding portion that is folded with a clamp of the transfer head;
lifting the transferer;
peeling off the protective film of the transferer;
picking up the light-emitting element from a donor substrate by adhering the light-emitting element to the transferer by the transfer head;
detaching the clamp from the folding portion by releasing the clamp and fixing the clamp to the folding portion;
arranging the light-emitting element on a circuit board by the transfer head; and
detaching the transferer from the transfer head.

23. The method of claim 22, further comprising
bonding the light-emitting element attached to the transferer onto the circuit board; and
removing the transferer by peeling it from the light-emitting element bonded to the circuit board by the transfer head.
